(19) United States
(12) Patent Application Publication
(10) Pub. No.: US 2026/0047083 A1
(43) Pub. Date: Feb. 12, 2026

(54) SEMICONDUCTOR DEVICE

(71) Applicant: Samsung Electronics Co., Ltd., Suwon-si (KR)

(72) Inventors: Jun Hee KIM, Suwon-si (KR); Jung-Hwan KIM, Suwon-si (KR); Tae-Eon Bae, Suwon-si (KR); Ho Kyun AN, Suwon-si (KR); Hee Ju YUN, Suwon-si (KR); Gil Woon LEE, Suwon-si, Gyeonggi-do (KR); Chun Hyung CHUNG, Suwon-si (KR)

(73) Assignee: Samsung Electronics Co., Ltd., Suwon-si (KR)

(21) Appl. No.: 19/052,843

(22) Filed: Feb. 13, 2025

(30) Foreign Application Priority Data
Aug. 8, 2024 (KR) 10-2024-0105890

(51) Int. Cl. H10B 12/00

(52) U.S. Cl. CPC H10B 12/50

(57) ABSTRACT

A semiconductor device is provided. The semiconductor device comprises a substrate, an active region disposed on or in the substrate, a gate interface film which is in contact with the active region, a dielectric film structure which is disposed on the gate interface film, and includes a metal silicon oxide, a gate electrode on the dielectric film structure, and a source/drain pattern which is disposed on both sides of the gate electrode. The dielectric film structure includes an impurity element doped to the metal silicon oxide, the dielectric film structure includes a first dielectric film region and a second dielectric film region, and a concentration of silicon of the first dielectric film region is greater than the concentration of silicon of the second dielectric film region.

### CROSS-REFERENCE TO RELATED APPLICATION

This application claims priority from Korean Patent Application No. 10-2024-0105890 filed on Aug. 8, 2024 in the Korean Intellectual Property Office, and all the benefits accruing therefrom under 35 U.S. C. 119, the contents of which in its entirety are herein incorporated by reference.

### BACKGROUND

### 1. Field of the Disclosure

The present disclosure relates to a semiconductor device.

### 2. Description of the Related Art

In recent years, semiconductor elements have been gradually scaled down with a high integration, and a low-power and high-speed operation of the transistor is required. A gate insulating film of the transistor is a unit element characteristic that is extremely important for the low-power and high-speed operation. A reduction in the electrical thickness of the gate insulating film and securement of the reliability characteristic (negative bias temperature instability (NBTI) lifetime) are importance most of all in the product development.

### SUMMARY

Aspects of the present disclosure provide a semiconductor memory device that may improve element performance and reliability.

According to an aspect of the present disclosure, there is provided a semiconductor device comprising a substrate, an active region disposed on or in the substrate, a gate interface film which is in contact with the active region, a dielectric film structure which is disposed on the gate interface film, and includes a metal silicon oxide, a gate electrode on the dielectric film structure, and a source/drain pattern which is disposed on both sides of the gate electrode. The dielectric film structure includes an impurity element doped to the metal silicon oxide, the dielectric film structure includes a first dielectric film region and a second dielectric film region, and a concentration of silicon of the first dielectric film region is greater than the concentration of silicon of the second dielectric film region.

According to an aspect of the present disclosure, there is provided a semiconductor device comprising a substrate, an active region disposed on or in the substrate, a gate interface film which is in contact with the active region, a dielectric film structure which is disposed on the gate interface film, and includes a metal silicon oxide, a gate electrode on the dielectric film structure, and a source/drain pattern which is disposed on both sides of the gate electrode. The dielectric film structure includes an impurity element doped to the metal silicon oxide, the dielectric film structure includes a first surface and a second surface that are opposite to each other in one direction, and the dielectric film structure includes a portion in which the concentration of silicon increases and then decreases, as it goes away from the first surface of the dielectric film structure.

According to an aspect of the present disclosure, there is provided a semiconductor device comprising a substrate which includes a memory cell region and a peri-region, a data storage pattern which is disposed in the memory cell region, and a peri-gate structure which is disposed on the peri-region. The peri-gate structure includes a gate interface film that is disposed on the substrate, a dielectric film structure which is disposed on the gate interface film and includes a metal silicon oxide, and a gate electrode on the dielectric film structure, the dielectric film structure includes an impurity element doped to the metal silicon oxide, the dielectric film structure includes a first dielectric film region and a second dielectric film region, and a concentration of silicon of the first dielectric film region is greater than the concentration of silicon of the second dielectric film region.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail illustrative embodiments thereof with reference to the attached drawings, in which:

FIG. 1 is an exemplary plan view for explaining a semiconductor device according to some embodiments.

FIG. 2 is an exemplary cross-sectional view taken along line A-A of FIG. 1 according to some embodiments.

FIG. 3 is an enlarged view of a region P1 of FIG. 2 according to some embodiments.

FIG. 4 is a schematic diagram showing the concentration of silicon (Si) and nitrogen (N) of the first and second dielectric film regions R1 and R2 of FIG. 3 according to some embodiments.

FIG. 5 is a diagram that schematically shows the concentrations of silicon (Si) and nitrogen (N) of regions R1 and R2 of FIG. 3 according to another embodiment.

FIG. 6 is an enlarged view of the region P1 of FIG. 2 according to another embodiment.

FIG. 7 is a diagram that schematically shows the concentrations of silicon (Si) and nitrogen (N) of the first to third dielectric film regions R1, R2, and R3 of FIG. 6 according to some embodiments.

FIG. 8 is a diagram showing the concentrations of silicon (Si) and nitrogen (N) of the first to third dielectric film regions R1, R2, and R3 of FIG. 6 according to another embodiment.

FIG. 9 is a layout diagram for explaining a semiconductor device according to some embodiments.

FIG. 10 is a cross-sectional view taken along B-B of FIG. 1.

FIG. 11 is a schematic layout diagram of a semiconductor device according to some embodiments.

FIG. 12 is a layout diagram of the cell array region of FIG. 11.

FIG. 13 is a cross-sectional view taken along lines C-C and D-D of FIG. 12.

FIG. 14 is a layout diagram for explaining a semiconductor memory device according to some embodiments.

FIG. 15 is a cross-sectional view taken along lines E-E and F-F of FIG. 14.

FIG. 16 is a diagram for explaining a semiconductor memory device according to another embodiment.

FIG. 17 is a schematic layout diagram of a semiconductor memory device according to some embodiments.

FIG. 18 is a layout of a region R that is a part of the cell region of FIG. 17.

FIG. 19 is a layout showing only the word line and the active region of FIG. 18.

FIG. 20 is a cross-sectional view taken along G-G of FIG. 18.

FIG. 21 is a diagram for illustrating a semiconductor memory device according to some implementations.

FIGS. 22 to 38 are intermediate stage diagrams for explaining a method for manufacturing a semiconductor memory device according to some embodiments.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

Although drawings of the semiconductor device according to some embodiments show a planar transistor, a transistor including a nanowire or a nanosheet, and a MBCFET™ (Multi-Bridge Channel Field Effect Transistor) or a vertical transistor (al FET) an example, the embodiment is not limited thereto. The semiconductor device according to some embodiments may, of course, include a tunneling transistor (tunneling FET), a fin-type transistor (FinFET) including a channel region of a fin-type pattern shape or a three-dimensional (3D) transistor. In addition, the technical idea of the present disclosure may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

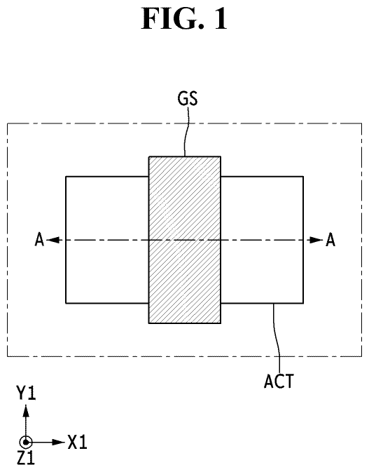

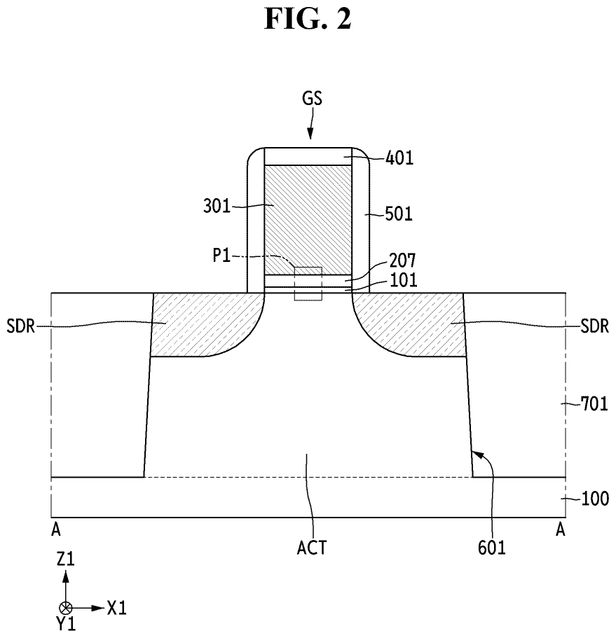

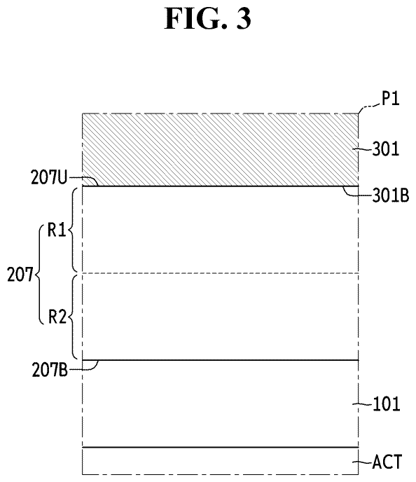

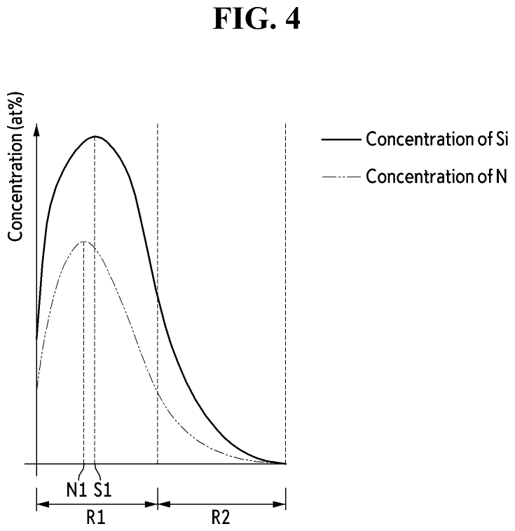

FIG. 1 is an exemplary plan view for explaining a semiconductor device according to some embodiments. FIG. 2 is an exemplary cross-sectional view taken along line A-A of FIG. 1 according to some embodiments. FIG. 3 is an enlarged view of a region P1 of FIG. 2 according to some embodiments. FIG. 4 is a schematic diagram showing the concentration of silicon (Si) and nitrogen (N) of the first and second dielectric film regions R1 and R2 of FIG. 3 according to some embodiments.

Reference to FIGS. 1 to 4, the semiconductor device according to some embodiments of the present disclosure may include a substrate 100, an element isolation film 701, and a gate structure GS.

The substrate 100 may be, for example, a silicon single crystal substrate or a silicon on insulator (SOI) substrate. In contrast, the substrate 100 may include, but not limited to, silicon germanium, silicon germanium on insulator (SGOI), indium antimonide, lead telluride, indium arsenide, indium phosphide, gallium arsenide or gallium antimonide.

A trench 601 may be disposed inside the substrate 100. An element isolation film 701 may be disposed inside the trench 601. The element isolation film 701 may define an active region ACT. In some embodiments, the active region ACT may extend in a first direction X1. For example, in FIG. 1, the active region ACT may include a long side extending in the first direction X1, and a short side extending in the second direction Y1. A length of the long side of the active region ACT is shown as being longer than a length of the short side of the active region ACT, but the embodiment is not limited thereto. As another example, the length of the long side of the active region ACT may be shorter than the length of the short side of the active region ACT.

In this specification, the first direction X1 and the second direction Y1 may intersect each other. The first direction X1 and the second direction Y1 may be substantially perpendicular to each other. The first direction X1 and the second direction Y1 may be directions that are parallel to an upper surface of the substrate 100. A third direction Z1 may intersect the first direction X1 and the second direction Y1. The third direction Z1 may be substantially perpendicular to the first direction X1 and the second direction Y1. The third direction Z1 may be perpendicular to the upper surface of the substrate 100.

A source/drain pattern SDR may be disposed inside the substrate 100. The source/drain pattern SDR may be disposed on one side and the other side of the gate structure GS. The source/drain pattern SDR may be doped with impurities. For example, the source/drain pattern SDR of the NMOS region may be doped with N-type impurities. The source/drain pattern SDR of the PMOS region may be doped with P-type impurities.

A gate structure GS may be disposed on the substrate 100. The gate structure GS may extend in the second direction Y1. In FIG. 1, the gate structure GS may include a long side extending in the second direction Y1, and a short side extending in the first direction X1. The length of the long side of the gate structure GS is longer than the length of the short side of the gate structure GS. In some embodiments, the width of the gate structure GS in the second direction Y1 may be greater than the width of the active region ACT in the second direction Y1. That is, the gate structure GS may include a portion that overlaps the element isolation film 701 in the third direction Z1. However, the technical idea of the present disclosure is not limited thereto.

The gate structure GS may include a gate interface film 101, a dielectric film structure 207, a gate electrode 301, a gate capping film 401, and a gate spacer 501. The gate interface film 101, the dielectric film structure 207, the gate electrode 301, and the gate capping film 401 may be sequentially stacked in the third direction Z1. The gate spacer 501 may be disposed along the side walls of the gate interface film 101, the dielectric film structure 207, the gate electrode 301, and the gate capping film 401.

The gate interface film 101 may extend along the upper surface of the active region ACT. The gate interface film 101 may include, for example, silicon oxide, silicon oxynitride or a combination thereof. Although FIG. 2 shows that the gate interface film 101 is formed of a single film, the technical idea of the present disclosure is not limited thereto. In some other embodiments, the gate interface film 101 may be formed of a multi-layer film.

The dielectric film structure 207 may be disposed on the gate interface film 101. The dielectric film structure 207 may be disposed between the gate interface film 101 and the gate electrode 301 to be described below.

The dielectric film structure 207 includes a metal silicon oxide. For example, the dielectric film structure 207 may include at least one of hafnium (Hf), lanthanum (La), zirconium (Zr), and aluminum (Al).

For reference, FIG. 4 shows only the concentration of silicon and the nitrogen concentration contained in the dielectric film structure 207 as a representative example, but the dielectric film structure 207 may include other elements other than silicon and nitrogen. Although FIG. 4 shows only a case in which the concentration of silicon contained in the dielectric film structure 207 is higher than the nitrogen concentration, the embodiment is not limited thereto. As another example, the dielectric film structure 207 may include a portion in which the concentration of silicon is lower than the nitrogen concentration. That is to say, the graph shown in FIG. 4 is only a graph for explaining each of tendencies of the concentration of silicon and the nitrogen concentration, but is not a graph for comparatively comparing the concentration of silicon and the nitrogen concentration.

The dielectric film structure 207 may include a first surface 207U and a second surface 207B that are opposite to each other. The first surface 207U may refer to the same surface as the lower surface 301B of the gate electrode 301.

As it goes away from the lower surface 301B of the gate electrode 301, the concentration of nitrogen and silicon contained in the dielectric film structure 207 may increase and then decrease. In other words, as it goes away from the first surface 207U, the concentration of nitrogen and silicon contained in the dielectric film structure 207 may increase and then decrease.

The concentration of nitrogen and silicon contained in the dielectric film structure 207 may be expressed in atomic percent (at. %), but is not limited thereto.

The dielectric film structure 207 may include a first dielectric film region R1 and a second dielectric film region R2. The first dielectric film region R1 and the second dielectric film region R2 may be divided depending on the distance away from the lower surface 301B of the gate electrode 301. Although the first dielectric film region R1 and the second dielectric film region R2 are shown to have the same thickness in FIG. 3, the embodiment is not limited thereto. As another example, the thickness of the first dielectric film region R1 may be thinner than the thickness of the second dielectric film region R2.

A point S1 at which the concentration of silicon contained in the dielectric film structure 207 is the highest is formed inside the first dielectric film region R1. In other words, the peak of the concentration of silicon graph is formed in the first dielectric film region R1.

The point N1 at which the concentration of nitrogen contained in the dielectric film structure 207 is the highest is formed inside the first dielectric film region R1. In other words, the peak of the nitrogen concentration graph is formed inside the first dielectric film region R1.

Although the point S1 at which the concentration of silicon is the highest and the point N1 at which the concentration of nitrogen is the highest are shown to be different from each other in FIG. 4, the embodiment is not limited thereto. As another example, the point S1 at which the concentration of silicon is the highest may be the same as the point N1 at which the concentration of nitrogen is the highest.

The first dielectric film region R1 includes a section in which the concentration of silicon increases and then decreases. The second dielectric film region R2 includes a section in which the concentration of silicon decreases. The first dielectric film region R1 includes a section in which the concentration of nitrogen increases and then decreases. The second dielectric film region R2 includes a section in which the concentration of nitrogen decreases.

For reference, FIG. 4 shows the concentration of silicon and the nitrogen concentration only in a tending manner. That is, for example, the second dielectric film region R2 may include a section in which the nitrogen concentration increases partially, but a common engineer may easily recognize that the section is a section in which the nitrogen concentration decrease in a tending manner.

The concentration profile of silicon and the concentration profile of nitrogen contained in the dielectric film structure 207 may be similar to each other. For example, the nitrogen concentration may also increase in the section in which the concentration of silicon increases. In the section in which the concentration of silicon decreases, the nitrogen concentration may also decrease.

As it comes closer to the gate interface film 101, the concentration of nitrogen contained in the dielectric film structure 207 decreases, and the threshold voltage may decrease. Accordingly, NBTI (Negative Bias Temperature Instability) lifetime characteristics may be improved.

The gate electrode 301 may be disposed on the dielectric film structure 207. The gate electrode 301 may extend in the second direction Y1. The gate electrode 301 may be formed of, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The gate electrode 301 may include a conductive metal oxide, conductive metal oxynitride, or the like, and may include an oxidized form of the aforementioned materials.

The gate capping film 401 may be disposed on the gate electrode 301. The gate capping film 401 may extend in the second direction Y1. The gate capping film 401 may include, for example, at least one of silicon nitride (SiN), silicon oxynitride (SiON), silicon oxide (SiO₂), silicon carbonitride (SiCN), silicon oxycarbonitride (SiOCN), and combinations thereof.

The gate spacer 501 may extend in the second direction Y1 along the side walls of the gate interface film 101, the dielectric film structure 207, the gate electrode 301, and the gate capping film 401. The gate spacer 501 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

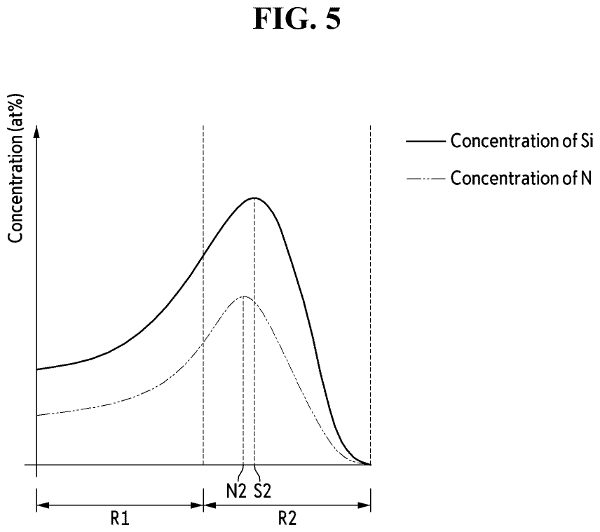

FIG. 5 is a diagram that schematically shows the concentrations of silicon (Si) and nitrogen (N) of regions R1 and R2 of FIG. 3 according to another embodiment. For convenience of explanation, FIG. 5 will mainly explain the differences from the semiconductor device shown in FIGS. 1 to 4.

Referring to FIG. 5, a point S2 at which the concentration of silicon contained in the dielectric film structure 207 is the highest is formed inside the second dielectric film region R2. In other words, a peak of the silicon concentration graph is formed inside the second dielectric film region R2.

A point N2 at which the concentration of nitrogen contained in the dielectric film structure 207 is the highest is formed inside the second dielectric film region R2. In other words, a peak of the nitrogen concentration graph is formed inside the second dielectric film region R2.

The first dielectric film region R1 includes a section in which the concentration of silicon increases. The second dielectric film region R2 includes a section in which the concentration of silicon increases and then decreases. The first dielectric film region R1 includes a section in which the concentration of nitrogen increases. The second dielectric film region R2 includes a section in which the concentration of nitrogen increases and then decreases.

The concentration of nitrogen contained in the dielectric film structure 207 decreases toward the active region ACT, and the threshold voltage may decrease. Accordingly, the NBTI lifetime characteristics may be improved.

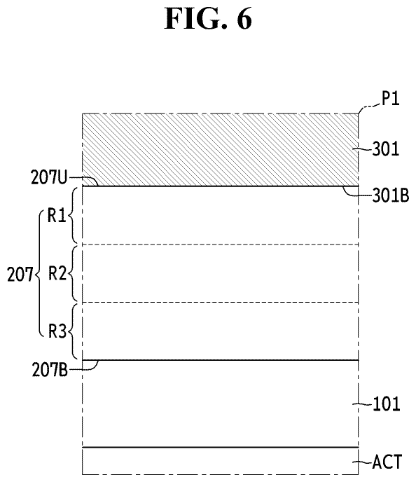

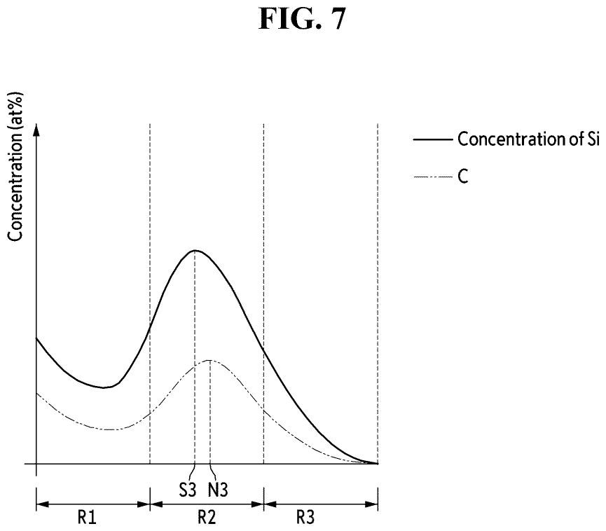

FIG. 6 is an enlarged view of the region P1 of FIG. 2 according to another embodiment. FIG. 7 is a diagram that schematically shows the concentrations of silicon (Si) and nitrogen (N) of the first to third dielectric film regions R1, R2, and R3 of FIG. 6 according to some embodiments. For convenience of explanation, in FIGS. 6 and 7, differences from the semiconductor device shown in FIGS. 1 to 4 will be mainly described.

Referring to FIGS. 6 and 7, the dielectric film structure 207 may include a first dielectric film region R1, a second dielectric film region R2, and a third dielectric film region R3. The first dielectric film region R1, the second dielectric film region R2, and the third dielectric film region R3 may be divided depending on the distance away from the lower surface 301B of the gate electrode 301. Although the first to third dielectric film regions R1, R2, and R3 are shown to have the same thickness in FIG. 6, the embodiment is not limited thereto. As another example, the thickness of the first dielectric film region R1 may be thinner than the thickness of the second dielectric film region R2.

The point S3 at which the concentration of silicon contained in the dielectric film structure 207 is the highest is formed inside the second dielectric film region R2. In other words, the peak of the concentration of silicon graph is formed inside the second dielectric film region R2.

The point N3 at which the concentration of nitrogen contained in the dielectric film structure 207 is the highest is formed inside the second dielectric film region R2. In other words, the peak of the nitrogen concentration graph is formed inside the second dielectric film region R2.

The first dielectric film region R1 may include, but not limited to, a section in which the concentration of silicon decreases and then increases. As another example, the concentration of silicon in the first dielectric film region R1 may only increase. The second dielectric film region R2 includes a section in which the concentration of silicon increases and then decreases. The third dielectric film region R3 includes a section in which the concentration of silicon decreases.

The first dielectric film region R1 may include, but not limited to, a section in which the concentration of nitrogen decreases and then increases. As another example, the concentration of nitrogen in the first dielectric film region R1 may only increase. The second dielectric film region R2 includes a section in which the concentration of nitrogen increases and then decreases. The third dielectric film region R3 includes a section in which the concentration of nitrogen decreases.

The concentration profile of silicon contained in the dielectric film structure 207 may be similar to the concentration profile of nitrogen. For example, the concentration of nitrogen may also increase in the section in which the concentration of silicon increases. The concentration of nitrogen may also decrease in the section in which the concentration of silicon decreases.

As it comes closer to the gate interface film 101, the concentration of nitrogen contained in the dielectric film structure 207 decreases, and the threshold voltage may decrease. Accordingly, the NBTI lifetime characteristics may be improved.

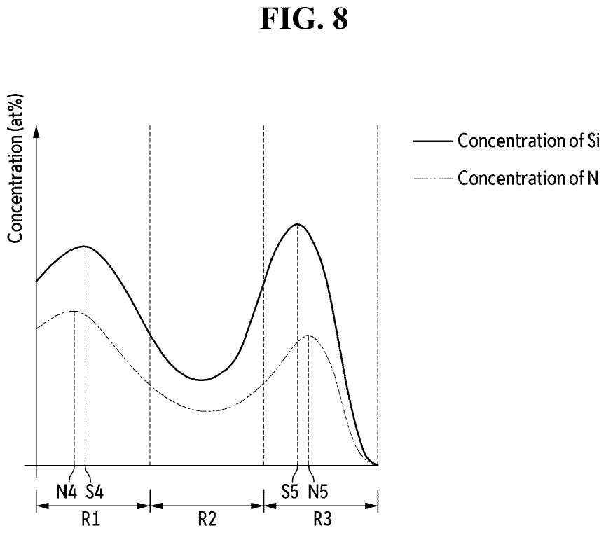

FIG. 8 is a diagram showing the concentrations of silicon (Si) and nitrogen (N) of the first to third dielectric film regions R1, R2, and R3 of FIG. 6 according to another embodiment. For convenience of explanation, FIG. 8 will mainly explain the differences from the semiconductor devices shown in FIGS. 1 to 4, 6, and 7.

Referring to FIG. 8, the points S4 and S5 at which the concentration of silicon contained in the dielectric film structure 207 is highest are formed inside the first dielectric film region R1 and the third dielectric film region R3. That is to say, a peak of the concentration of silicon graph is formed in the first dielectric film region R1 and the third dielectric film region R3.

Points N4 and N5 at which the concentration nitrogen contained in the dielectric film structure 207 is the highest are formed inside the first dielectric film region R1 and the third dielectric film region R3. That is to say, a peak of the nitrogen concentration graph is formed in the first dielectric film region R1 and the third dielectric film region R3.

The first dielectric film region R1 and the third dielectric film region R3 include a section in which the concentration of silicon increases and then decreases. The second dielectric film region R2 includes a section in which the concentration of silicon decreases and then increases.

The first dielectric film region R1 and the third dielectric film region R3 include a section in which the concentration of nitrogen increases and then decreases. The second dielectric film region R2 includes a section in which the concentration of nitrogen decreases and then increases.

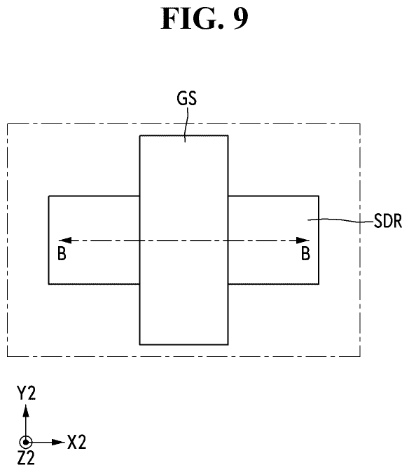

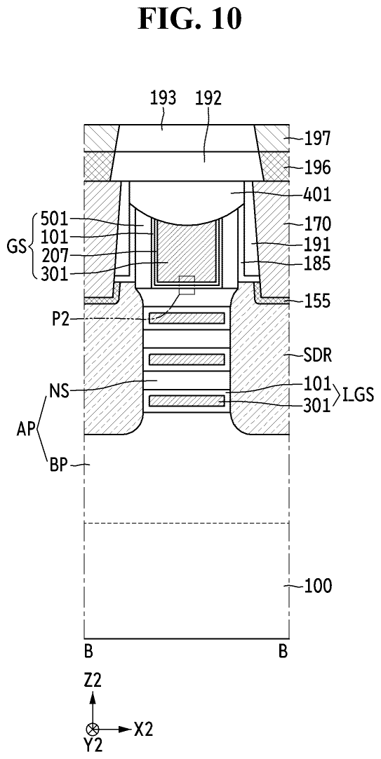

FIG. 9 is a layout diagram for explaining a semiconductor device according to some embodiments. FIG. 10 is a cross-sectional view taken along B-B of FIG. 1. For convenience of explanation, in FIGS. 9 and 10, differences from the semiconductor device shown in FIGS. 1 to 4 will be mainly explained.

Referring to FIGS. 9 and 10, a semiconductor device according to some embodiments may include a substrate 100, a gate structure GS, a source/drain pattern SDR, a source/drain etching stop film 185, a first interlayer insulating film 191, a source/drain contact 170, a contact silicide film 155, a wiring via 196, a wiring line 197, a second interlayer insulating film 192, and a third interlayer insulating film 193.

The lower pattern BP may protrude from the substrate 100. A plurality of sheet patterns NS may be disposed on the lower pattern BP. A plurality of sheet patterns NS may be disposed on the upper surface of the substrate 100.

The lower pattern BP may be formed by etching a part of the substrate 100, and may include an epitaxial layer grown from the substrate 100. The lower pattern BP may include silicon or germanium, which are elemental semiconductor materials. The lower pattern BP may also include a compound semiconductor, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping these elements with a group IV element.

The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The plurality of sheet patterns NS may include one of silicon or germanium, which are elemental semiconductor materials, the group IV-IV compound semiconductors, or the group III-V compound semiconductors. Taking the sheet pattern NS as an example, a width of the sheet pattern NS in a fifth direction Y2 may become increase or decrease in proportion to a width of the first lower pattern BP in the fifth direction Y2. The widths of each sheet pattern NS disposed on the first lower pattern BP in the fifth direction Y2 are shown as being the same, but the embodiment is not limited thereto.

The gate structure GS may be disposed on the substrate 100. The gate structure GS may extend in the fifth direction Y2. The gate structure GS may intersect the lower pattern BP. The gate structure GS may wrap the sheet pattern NS.

The gate structure GS may include a plurality of inner gate structures I_GS which are disposed between the sheet patterns NS adjacent in a sixth direction Z2, and between the lower pattern BP and the sheet pattern NS. The number of the inner gate structures I_GS may be the same as the number of the sheet patterns NS. In the semiconductor device according to some embodiments, the inner gate structure I_GS may come into contact with a source/drain pattern SDR to be described below.

The inner gate structure GS may include a gate electrode 301 and a gate interface film 101 that are disposed between the adjacent sheet patterns NS, and between the lower pattern BP and the sheet pattern NS. The gate electrode 301 may be disposed on the lower pattern BP. The gate electrode 301 may wrap the sheet pattern NS.

In the cross-sectional view such as FIG. 10, the upper surface of the gate electrode 301 is shown as being a concave curved surface, but the embodiment is not limited thereto. It goes without saying that the upper surface of the gate electrode 301 may be a plane.

The gate electrode 301 may be disposed on the gate interface film 101. The gate interface film 101 may be disposed between the gate electrode 301 and the sheet pattern NS. In the semiconductor device according to some embodiments, the gate interface film 101 included in the inner gate structure I_GS may come into contact with the source/drain pattern SDR.

The semiconductor device according to some embodiments may include an NC (Negative Capacitance) FET that uses a negative capacitor. For example, each gate interface film 101 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. A thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, the gate interface film 101 may include one ferroelectric material film. As another example, the gate interface film 101 may include a plurality of ferroelectric material films spaced apart from each other. The gate interface film 101 may have a stacked film structure in which the plurality of ferroelectric material films and the plurality of paraelectric material films are alternately stacked.

The gate spacer 501 may be disposed on a side wall of the gate interface film 101. The gate capping film 401 may be disposed on the gate electrode 301. Unlike the shown example, the gate capping film 401 may be disposed between the gate spacers 501.

The source/drain pattern SDR may be disposed on the lower pattern BP. The source/drain pattern SDR may be disposed between the gate electrodes 301 that are adjacent to each other in the fourth direction X2. The source/drain pattern SDR may come into contact with the sheet pattern NS. The source/drain pattern SDR may be connected to the sheet pattern NS and the lower pattern BP. The source/drain pattern SDR may be included in the source/drain of a transistor that uses the sheet pattern NS as a channel region. The source/drain pattern SDR may include an epitaxial pattern. The source/drain pattern SDR may include a semiconductor material.

The source/drain etching stop film 185 may extend along the outer wall of the gate spacer 501 and the side wall of the source/drain pattern SDR. The source/drain etching stop film 185 may not extend along the side wall of the gate capping layer 401. Unlike the shown example, the source/drain etching stop film 185 may extend along the side wall of the gate capping layer 401.

The source/drain etching stop film 185 may include, for example, at least one of silicon nitride (SiN), silicon oxynitride (SiON), oxycarbonitride (SiOCN), silicon boronitride (SiBN), silicon oxyboronitride (SiOBN), silicon oxycarbide (SiOC), and combinations thereof.

The first interlayer insulating film 191 may be disposed on the source/drain pattern SDR. The first interlayer insulating film 191 may not cover the upper surface of the gate capping film 401. The first interlayer insulating film 191 may include, for example, at least one of silicon oxide, silicon nitride, silicon oxynitride, and a low dielectric constant material.

The source/drain contact 170 may be disposed on the source/drain pattern SDR. The source/drain contact 170 is electrically connected to the source/drain pattern SDR. The source/drain contact 170 is shown to have a single conductive film structure, but is not limited thereto. Unlike the shown example, the source/drain contact 170 may have multi-conductive film structures including a barrier film and a plug film. The source/drain contact 170 may include, for example, at least one of a metal, a conductive metal nitride, a conductive metal carbide, a conductive metal oxide, a conductive metal carbonitride, and a two-dimensional (2D) material.

The contact silicide film 155 may be disposed between the source/drain pattern SDR and the source/drain contact 170. The contact silicide film 155 may include a metal silicide material. The two-dimensional material (2D material) may include a two-dimensional allotrope or a two-dimensional compound, and may include, but not limited to, at least one of graphene, boron nitride (BN), molybdenum sulfide, molybdenum selenide, tungsten sulfide, tungsten selenide, and tantalum sulfide. That is, the above-mentioned two-dimensional materials are merely listed as examples, and the two-dimensional materials that may be included in the semiconductor device of the present disclosure are not limited to the above-mentioned materials.

The second interlayer insulating film 192 may be disposed on the source/drain contact 170 and the gate capping film 401. The third interlayer insulating film 193 may be disposed on the second interlayer insulating film 192. Each of the second interlayer insulating film 192 and the third interlayer insulating film 193 may include, for example, at least one of silicon oxide, silicon nitride, silicon oxynitride, and a low dielectric constant material.

The wiring via 196 may be disposed inside the second interlayer insulating film 192. The wiring via 196 may be connected to the source/drain contact 170. The wiring line 197 may be disposed inside the third interlayer insulating film 193. The wiring line 197 may be connected to the wiring via 196. The wiring line 197 may be connected to the source/drain contact 170 through the wiring via 196.

Each of the wiring via 196 and the wiring line 197 is shown to have a single conductive film structure, but the embodiment is not limited thereto. Each of the wiring via 196 and the wiring line 197 may include at least one of, for example, a metal, a conductive metal nitride, a conductive metal carbide, a conductive metal oxide, a conductive metal carbonitride, and a two-dimensional material.

The region P2 shown in FIG. 10 may correspond to the region P1 shown in FIG. 2.

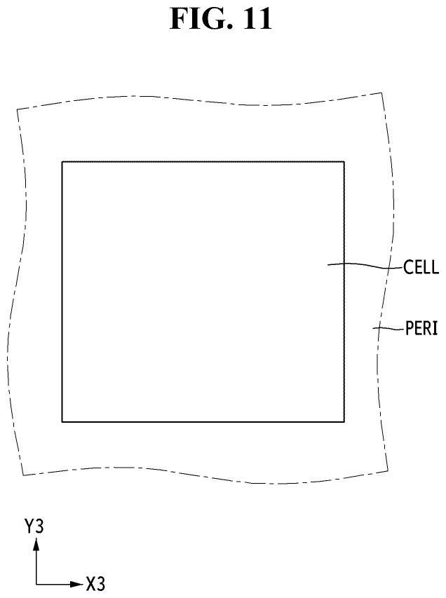

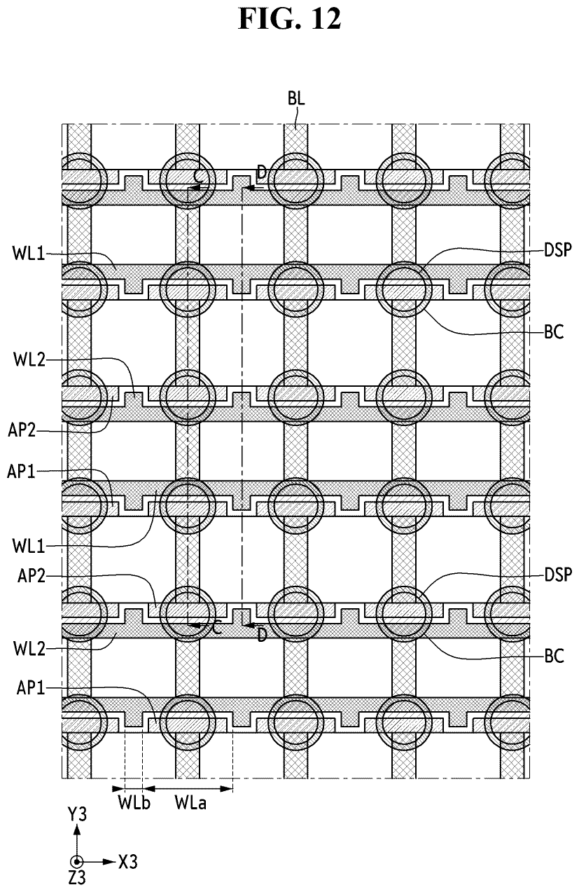

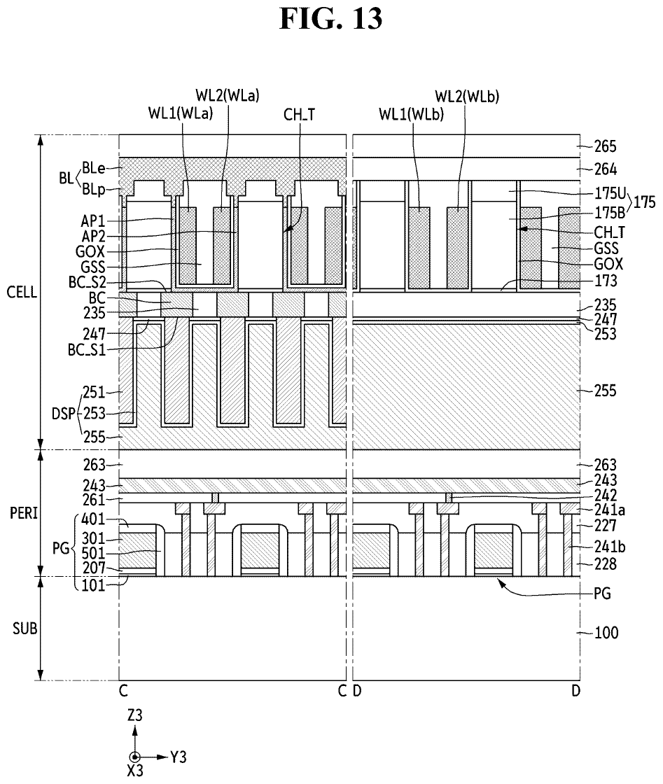

FIG. 11 is a schematic layout diagram of a semiconductor device according to some embodiments. FIG. 12 is a layout diagram of the cell array region of FIG. 11. FIG. 13 is a cross-sectional view taken along lines C-C and D-D of FIG. 12. For convenience of explanation, FIGS. 11 to 13 will mainly explain the differences from the semiconductor device shown in FIGS. 1 to 4.

Referring to FIGS. 11 to 13, the semiconductor memory device according to an embodiment of the present disclosure may include memory cells including a vertical channel transistor (VCT).

The semiconductor memory device according to some embodiments may include a peri-gate structure PG, bit lines BL, word lines WL1 and WL2, first channel patterns AP1, second channel patterns AP2, contact patterns BC, and data storage patterns DSP.

The substrate 100 may include a cell array region CELL in which the data storage pattern DSP is disposed, and a peripheral circuit region PERI defined around the cell array region CELL.

The peri-gate structure PG may be disposed on the substrate 100. The substrate 100 may include a cell array region CELL and a peripheral circuit region PERI. The peri-gate structure PG may be disposed over the cell array region CELL and the peripheral circuit region PERI. In other words, a part of the peri-gate structure PG may be disposed in the cell array region CELL of the substrate 100, and the remainder of the peri-gate structure PG may be disposed in the peripheral circuit region PERI of the substrate 100.

The peri-gate structure PG may correspond to the semiconductor device shown in FIGS. 1 to 4. That is, the peri-gate structure GS may include a gate interface film 101, a dielectric film structure 207, a gate electrode 301, a gate capping film 401, and a gate spacer 501.

The peri-wiring line 241a and the peri-contact plug 241b may be disposed inside the first peri-lower insulating film 227 and the second peri-lower insulating film 228. The peri-contact plug 241b may be connected to a source/drain region disposed on at least one side of the peri-gate structure PG. For example, the source/drain region may be, but not limited to, a region in which the substrate 100 is doped with impurities. Although not shown, the peri-contact plug 241b may be connected to the gate electrode 301 of the peri-gate structure PG.

The peri-wiring line 241a may be disposed on the peri-contact plug 241b. The peri-wiring line 241a is connected to the peri-contact plug 241b. For example, the peri-wiring line 241a may be the wiring line that is closest to the peri-gate structure PG in a ninth direction Z3.

The peri-wiring line 241a and the peri-contact plug 241b are shown as being different films from each other, but the embodiment is not limited thereto. A boundary between the peri-wiring line 241a and the peri-contact plug 241b may not be distinguished. Each of the peri-wiring line 241a and the peri-contact plug 241b includes a conductive material.

The first peri-upper insulating film 261 may be disposed on the peri-wiring line 241a and the peri-contact plug 241b. The first peri-upper insulating film 261 may be formed of an insulating material. The peri-connecting wiring 243 and the peri-connecting via 242 may be disposed on the peri-wiring line 241a. The peri-connecting via 242 may be disposed inside the peri-upper insulating film 261.

The peri-connecting wiring 243 and the peri-connecting via 242 are connected to the peri-wiring line 241a. The peri-connecting via 242 may connect the peri-wiring line 241a and the peri-connecting wiring 243. Each of the peri-connecting wiring 243 and the peri-connecting via 242 includes a conductive material. The peri-connecting wiring 243 and the peri-connecting via 242 are shown to be different films from each other, but the embodiment is not limited thereto. A boundary between the peri-connecting wiring 243 and the peri-connecting via 242 may not be distinguished.

Although the peri-connecting wiring disposed at one metal level is shown to be disposed on the peri-wiring line 241a, this is only for convenience of explanation, and the embodiment is not limited thereto. It goes without saying that a plurality of peri-connecting wirings 243 disposed at different metal levels from each other may be disposed on the peri-wiring line 241a unlike the shown example.

The first interlayer insulating film 263 may be disposed on the peri-connecting wiring 243. The first interlayer insulating film 263 may include an insulating material.

The data storage patterns DSP may be disposed on the first interlayer insulating film 263. The first interlayer insulating film 263 may be disposed between the data storage pattern DSP and the peri-connecting wiring 243.

The data storage patterns DSP may be electrically connected to each of the first and second channel patterns AP1 and AP2. The data storage patterns DSP may be disposed in the form of a matrix along a seventh direction X3 and an eighth direction Y3.

Here, the seventh direction X3 and the eighth direction Y3 may be perpendicular to the ninth direction Z3. The seventh direction X3 may intersect the eighth direction Y3. For example, the ninth direction Z3 may be a thickness direction of the substrate 100. The seventh direction X3 and the eighth direction Y3 may be parallel to the upper surface of the substrate 100.

As an example, the data storage patterns DSP may be capacitors. The data storage patterns DSP may include a capacitor dielectric film 253 interposed between the storage electrode 251 and the plate electrode 255. From a planar viewpoint, the storage electrode 251 may have various shapes, such as a circle, an ellipse, a rectangle, a square, a rhombus, and a hexagon. The storage electrodes 251 may penetrate the first etching stop film 247. The first etching stop film 247 may be made of an insulating material.

Each of the storage electrode 251 and the plate electrode 255 may include, for example, at least one of a conductive semiconductor material, a conductive metal nitride, a conductive metal silicon nitride, a metal carbonitride, a conductive metal silicide, a conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, a combination of the ferroelectric and antiferroelectric materials, a combination of the ferroelectric and paraelectric materials, a combination of paraelectric and antiferroelectric materials, and a combination of the ferroelectric material, the antiferroelectric material and the paraelectric material.

In contrast, the data storage patterns DSP may be variable resistance patterns that may be switched into two resistance statuses by electrical pulses applied to the memory element. For example, the data storage patterns DSP may include a phase-change material whose crystal status changes depending on the amount of current, perovskite compounds, transition metal oxide, magnetic materials, ferromagnetic materials or antiferromagnetic materials.

Contact patterns BC may be disposed on the data storage patterns DSP. The contact patterns BC may be disposed on the storage electrodes 251, respectively. The storage electrodes 251 may come into contact with the contact patterns BC. The contact patterns BC may have various shapes such as a circle, an ellipse, a rectangle, a square, a rhombus or a hexagon from the planar viewpoint.

A contact isolation insulating film 235 may be disposed on the first etching stop film 247. The contact isolation insulating film 235 may be disposed between the contact patterns BC. From a planar viewpoint, the contact patterns BC may be disposed in the form of a matrix along the seventh direction X3 and the eighth direction Y3. The contact isolation insulating film 235 may be made of an insulating material.

The data storage patterns DSP may completely or partially overlap the contact patterns BC in the ninth direction Z3.

The contact pattern BC includes a conductive material. The contact pattern BC may include at least one of, for example, doped polysilicon, conductive metal nitride, conductive metal silicon nitride, metal carbonitride, conductive metal silicide, conductive metal oxide, two-dimensional material, metal, and metal alloy.

A protruding insulating pattern 175 may be disposed on the contact pattern BC and the contact isolation insulating film 235. A second etching stop film 173 may be disposed between the protruding insulating pattern 175 and the contact isolation insulating film 235.

The protruding insulating pattern 175 may include an upper protruding insulating pattern 175U and a lower protruding insulating pattern 175B. The lower protruding insulating pattern 175B may be disposed between the upper protruding insulating pattern 175U and the contact pattern BC, and between the upper protruding insulating pattern 175U and the contact isolation insulating film 235. The lower protruding insulating pattern 175B may be disposed between the upper protruding insulating pattern 175U and the second etching stop film 173.

Each of the upper protruding insulating pattern 175U and the lower protruding insulating pattern 175B may be made of an insulating material. The upper protruding insulating pattern 175U and the lower protruding insulating pattern 175B may include different insulating materials from each other. In the semiconductor memory device according to some embodiments, the upper protruding insulating pattern 175U may include silicon nitride, and the lower protruding insulating pattern 175B may include silicon oxide.

The second etching stop film 173 may be formed of an insulating material. The second etching stop film 173 may include a material having an etch selectivity with respect to the lower protruding insulating pattern 175B. Unlike the shown example, the second etching stop film 173 may not be disposed between the lower protruding insulating pattern 175B and the cell lower insulating layer 171.

The protruding insulating pattern 175 is shown to have a double film structure, but is not limited thereto. Unlike the shown example, as an example, the protruding insulating pattern 175 may have a single film structure. When the protruding insulating pattern 175 has a single film structure, the protruding insulating pattern 175 may include, but not limited to, silicon oxide. As another example, the protruding insulating pattern 175 may have an insulating pattern structure of three or more films. In such a case, the protruding insulating pattern 175 may have a stacked insulating film structure in which silicon oxide, silicon nitride, and silicon oxide are stacked, but the embodiment is not limited thereto.

The protruding insulating pattern 175 may include a plurality of channel trenches CH_T. Each channel trench CH_T may extend long in the seventh direction X3. Adjacent channel trenches CH_T may be spaced apart in the eighth direction Y3.

Each channel trench CH_T may expose the contact patterns BC. The second surface BC_S2 of each contact pattern may be exposed by the channel trench CH_T. For example, in each contact pattern BC, a part of the second surface BC_S2 of the contact pattern may be exposed by the channel trench CH_T.

The contact isolation insulating film 235 may include a first region that overlaps the channel trench CH_T in the ninth direction Z3, and a second region that does not overlap the channel trench CH_T in the ninth direction Z3. The contact isolation insulating film 235 may include a first surface and a second surface that are opposite to each other in the ninth direction Z3. The first surface of the contact isolation insulating film 235 may face the data storage pattern DSP.

The side wall of each channel trench CH_T may be defined by the lower protruding insulating pattern 175B, the upper protruding insulating pattern 175U, and the second etching stop film 173. If the second etching stop film 173 is not disposed, the side wall of each channel trench CH_T may be defined by the lower protruding insulating pattern 175B and the upper protruding insulating pattern 175U.

The first channel pattern AP1 and the second channel pattern AP2 may be disposed on the data storage pattern DSP. The data storage pattern DSP may be disposed between the first channel pattern AP1 and the substrate 100. The data storage pattern DSP may be disposed between the second channel pattern AP2 and the substrate 100.

The first channel pattern AP1 and the second channel pattern AP2 may be disposed on the contact pattern BC. Each of the first channel pattern AP1 and the second channel pattern AP2 may be connected to the contact pattern BC.

The first channel patterns AP1 may be spaced apart from each other in the seventh direction X3. The first channel patterns AP1 may be spaced apart at regular intervals. The second channel patterns AP2 may be spaced apart from each other in the seventh direction X3. The second channel patterns AP2 may be spaced apart at regular intervals. The first channel pattern AP1 may be spaced apart from the second channel pattern AP2 in the eighth direction Y3. The first and second channel patterns AP1 and AP2 may be arranged two-dimensionally along the seventh direction X3 and the eighth direction Y3.

The first channel pattern AP1 and the second channel pattern AP2 may be disposed inside a channel trench CH_T extending in the seventh direction X3. A plurality of first channel patterns AP1 may be disposed inside one channel trench CH_T. A plurality of second channel patterns AP2 may be disposed inside one channel trench CH_T.

The first channel pattern AP1 and the second channel pattern AP2 may include an oxide semiconductor material. The first channel pattern AP1 and the second channel pattern AP2 may include, for example, a metal oxide. As an example, the first channel pattern AP1 and the second channel pattern AP2 may be an amorphous metal oxide film. As another example, the first channel pattern AP1 and the second channel pattern AP2 may be a polycrystalline metal oxide film. As yet another example, the first channel pattern AP1 and the second channel pattern AP2 may be in a status in which an amorphous metal oxide film and a polycrystalline metal oxide film are combined. As yet another example, the first channel pattern AP1 and the second channel pattern AP2 may be a CAAC (c-axis aligned crystalline) metal oxide film.

The first channel pattern AP1 and the second channel pattern AP2 may include, for example, but not limited to, at least one of indium oxide, tin oxide, zinc oxide, In-Zn-based oxide (IZO), Sn-Zn-based oxide, Al-Zn-based oxide, Zn-Mg-based oxide, Sn-Mg-based oxide, In-Mg-based oxide, In-Ga-based oxide (IGO), In-Ga-Zn-based oxide (IGZO), In-Al-Zn-based oxide, In-Sn-Zn-based oxide, Sn-Ga-Zn-based oxide, Al-Ga-Zn-based oxide, Sn-Al-Zn-based oxide, In-Hf-Zn-based oxide, In-La-Zn-based oxide, In-Ce-Zn-based oxide, In-Pr-Zn-based oxide, In-Nd-Zn-based oxide, In-Sm-Zn-based oxide, In-Eu-Zn-based oxide, In-Gd-Zn-based oxide, In-Tb-Zn-based oxide, In-Dy-Zn-based oxide, In-Ho-Zn-based oxide, In-Er-Zn-based oxide, In-Tm-Zn-based oxide, In-Yb-Zn-based oxide, In-Lu-Zn-based oxide, In-Sn-Ga-Zn-based oxide, In-Hf-Ga-Zn-based oxide, In-Al-Ga-Zn-based oxide, In-Sn-Al-Zn-based oxide, In-Sn-Hf-Zn-based oxide, and In-Hf-Al-Zn-based oxide.

Here, the In-Ga-Zn-based oxide means an oxide that has In, Ga, and Zn as main constituents, but does not mean a ratio of In, Ga, and Zn. That is, taking IGZO (indium gallium zinc oxide) as an example, the channel structure AP_ST may include IGZO (indium gallium zinc oxide, InₓGa_{y}Zn_{z}O). The IGZO (In:Ga:Zn=1:1:1) containing indium, gallium and zinc at the same ratio may be an In-Ga-Zn-based oxide. A Ga-rich IGZO may have a higher ratio of gallium than the IGZO (In:Ga:Zn=1:1:1), and a lower ratio of indium than the IGZO (In:Ga:Zn=1:1:1). The Ga-rich IGZO may also be an In-Ga-Zn-based oxide. Further, an In-rich IGZO may also have a higher ratio of indium than IGZO (In:Ga:Zn=1:1:1) and a lower ratio of gallium than IGZO (In:Ga:Zn=1:1:1). The In-rich IGZO may also be an In-Ga-Zn-based oxide.

Although the above description has been made using the IGZO, the embodiment is not limited thereto. Needless to say, the above description may be applied when the first channel pattern AP1 and the second channel pattern AP2 include a ternary or more metal oxide. Also, the first channel pattern AP1 and the second channel pattern AP2 may further include a doped metal element other than In, Ga, and Zn, when the first channel pattern AP1 and the second channel pattern AP2 include the In-Ga-Zn-based oxide.

A first word line WL1 may be disposed on the first channel pattern AP1. The second word line WL2 may be disposed on the second channel pattern AP2. The first word line WL1 and the second word line WL2 may be disposed in the channel trench CH_T.

Each of the first word line WL1 and the second word line WL2 may extend in the seventh direction X3. The first word line WL1 and the second word line WL2 may be alternately arranged in the eighth direction Y3. The first word line WL1 is spaced apart from the second word line WL2 in the eighth direction Y3.

The first word line WL1 and the second word line WL2 are spaced apart from a bit line BL in the ninth direction Z3. The first word line WL1 and the second word line WL2 intersect the bit line BL. The first word line WL1 and the second word line WL2 are spaced apart from the contact pattern BC in the ninth direction Z3.

The first word line WL1 and the second word line WL2 are disposed between the first channel pattern AP1 and the second channel pattern AP2. The first channel pattern AP1 is closer to the first word line WL1 than the second word line WL2. The second channel pattern AP2 is closer to the second word line WL2 than the first word line WL1.

Each of the first word line WL1 and the second word line WL2 may have a width in the eighth direction Y3. The width of the first word line WL1 in the portion that overlaps the first and second channel patterns AP1 and AP2 in the ninth direction Z3 may be different from the width of the first word line WL1 in the portion that does not overlap the first and second channel patterns AP1 and AP2. The width of the second word line WL2 in the portion that overlaps the first and second channel patterns AP1 and AP2 in the ninth direction Z3 may be different from the width of the second word line WL2 in the portion that does not overlap the first and second channel patterns AP1 and AP2.

For example, each of the first word lines WL1 and the second word lines WL2 may include a first portion WLa of the word line, and a second portion WLb of the word line. The width of the first portion WLa of the word line in the eighth direction Y3 may be smaller than the width of the second portion WLb of the word line in the eighth direction Y3. As an example, the first portion WLa of the word line may be disposed on the first channel pattern AP1 and the second channel pattern AP2.

Each of the first word lines WL1 and the second word lines WL2 may include the first portion WLa of the word line and the second portion WLb of the word line that are alternately disposed along the seventh direction X3. In the first word lines WL1, each of the first channel patterns AP1 may be disposed between the second portions WLb of the word lines adjacent to each other in the seventh direction X3. In the second word lines WL2, each of the second channel patterns AP2 may be disposed between the second portions WLb of the word lines adjacent to each other in the seventh direction X3.

Unlike the shown example, the width of the first portion WLa of the word line in the eighth direction Y3 may be the same as the width of the second portion WLb of the word line in the eighth direction Y3. In such a case, a gate insulating film GOX to be described below may fill the space between the first channel patterns AP1 adjacent to each other in the seventh direction X3 and the space between the second channel patterns AP2 adjacent to each other in the seventh direction X3.

The first word line WL1 and the second word line WL2 include a conductive material, and may include, for example, at least one of doped polysilicon, conductive metal nitride, conductive metal silicon nitride, metal carbonitride, conductive metal silicide, conductive metal oxide, two-dimensional material, metal, and metal alloy.

The gate insulating film GOX may be disposed between the first word line WL1 and the first channel pattern AP1, and between the second word line WL2 and the second channel pattern AP2. The gate insulating film GOX may extend in the seventh direction X3 alongside the first word line WL1 and the second word line WL2.

From the viewpoint of the cross-sectional view, the gate insulating film GOX between the first word line WL1 and the first channel pattern AP1 may be directly connected to the gate insulating film GOX between the second word line WL2 and the second channel pattern AP2. Unlike the shown example, the gate insulating film GOX between the first word line WL1 and the first channel pattern AP1 may be separated from the gate insulating film GOX between the second word line WL2 and the second channel pattern AP2.

The gate insulating film GOX may include a silicon oxide film, a silicon oxynitride film, a high dielectric constant insulating film having a higher dielectric constant than the silicon oxide film, or a combination thereof. For example, the gate insulating film GOX may include, but not limited to, aluminum oxide. A part of the gate insulating film GOX may protrude in the ninth direction Z3 beyond the upper surface of the first and second word lines WL1 and WL2.

A gate isolation pattern GSS may be disposed between the first word line WL1 and the second word line WL2 that are adjacent to each other in the eighth direction Y3. The first word line WL1 and the second word line WL2 may be separated by the gate isolation pattern GSS. The gate isolation pattern GSS may extend in the seventh direction X3 between the first word line WL1 and the second word line WL2.

The first word line WL1 may be disposed between the gate isolation pattern GSS and the first channel pattern AP1. The second word line WL2 may be disposed between the gate isolation pattern GSS and the second channel pattern AP2.

The gate isolation pattern GSS may be made of an insulating material. Although the gate insulation pattern GSS is shown as being a single film, this is only for convenience of explanation, and the embodiment is not limited thereto.

The bit line BL is disposed on the first channel pattern AP1 and the second channel pattern AP2. The bit line BL may be connected to the first channel pattern AP1 and the second channel pattern AP2. The bit line BL may extend long in the eighth direction Y3. Adjacent bit lines BL may be spaced apart in the seventh direction X3. In the semiconductor memory device according to some embodiments, the data storage pattern DSP may be disposed between the peri-gate structure PG and the bit line BL.

The bit line BL may include an extension BLe and a protrusion BLp. The extension BLe of the bit line may extend in the eighth direction Y3. The protrusion BLp of the bit line may protrude in the ninth direction Z3. The protrusion BLp of the bit line may protrude from the extension BLe of the bit line toward the first channel pattern AP1. The protrusion BLp of the bit line may protrude from the extension BLe of the bit line toward the second channel pattern AP1.

The protrusion BLp of the bit line may be connected to the first channel pattern AP1 and the second channel pattern AP2. The protrusion BLp of the bit line may connect the first channel pattern AP1 and the extension BLe of the bit line. The protrusion BLp of the bit line may connect the second channel pattern AP2 and the extension BLe of the bit line. The protrusion BLp of the bit line may include the lowermost part of the bit line BL on the basis of the second surface BC_S2 of the contact pattern.

The bit line BL may include, for example, at least one of a doped semiconductor material, a conductive metal nitride, a conductive metal silicon nitride, a metal carbonitride, a conductive metal silicide, a conductive metal oxide, a two-dimensional material, and a metal. Although the bit line BL is shown to be a single film, this is only for convenience of explanation, and the embodiment is not limited thereto.

A third interlayer insulating film 265 may be disposed on the bit line BL and the second interlayer insulating film 264. Each of the second interlayer insulating film 264 and the third interlayer insulating film 265 may include an insulating material.

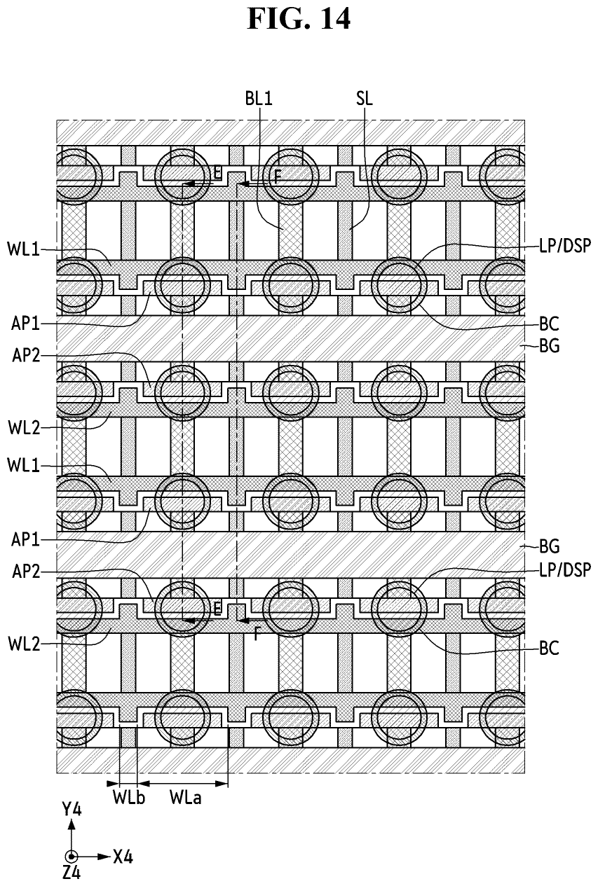

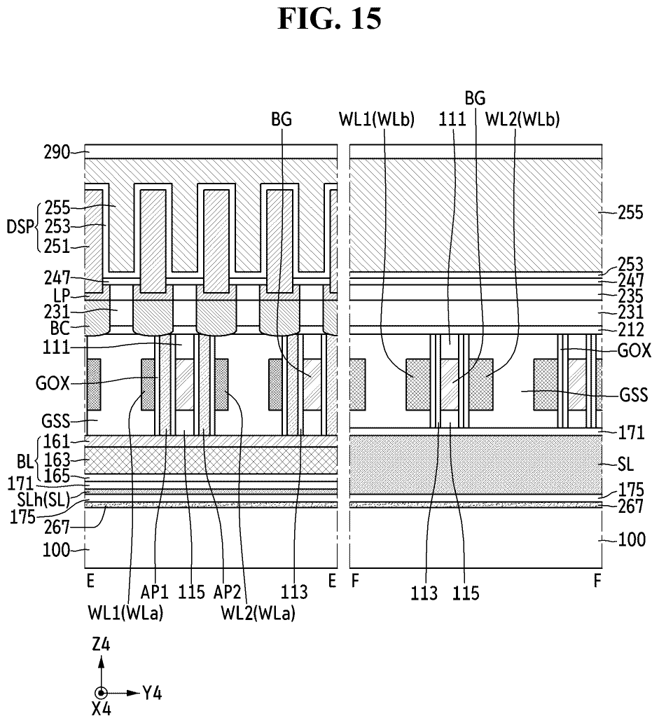

FIG. 14 is a layout diagram for explaining a semiconductor memory device according to some embodiments. FIG. 15 is a cross-sectional view taken along lines E-E and F-F of FIG. 14. For convenience of explanation, in FIGS. 14 and 15, differences from the semiconductor device shown in FIGS. 1 to 4 will be mainly explained.

The semiconductor memory device according to some embodiments of the present disclosure may include memory cells including a vertical channel transistor (VCT).

Referring to FIGS. 14 and 15, a semiconductor memory device according to some embodiments may include bit lines BL, first word lines WL1, second word lines WL2, back gate electrodes BG, a shielding conductive pattern SL, first active patterns AP1, second active patterns AP2, and data storage patterns DSP.

The bonding insulating film 267 may be disposed on the substrate 100. The bonding insulating film 267 may be used to bond the wafer. As an example, the bonding insulating film 267 may include silicon carbonitride (SiCN). As another example, the bonding insulating film 267 may include silicon oxide (SiO₂).

The shielding structures 171, SL and 175 may be disposed on the substrate 100. For example, the shielding structures 171, SL and 175 may be disposed on the bonding insulating film 267.

The shielding structures 171, SL and 175 may include a shielding conductive pattern SL, and shielding insulating films 171 and 175. For example, the shielding insulating films 171 and 175 may include a shielding insulating liner 171 and a shielding insulating capping film 175.

The shielding conductive pattern SL may include a shielding conductive plate SLh and a plurality of shielding conductive line patterns SLp. The shielding conductive plate SLh may have a flat plate shape.

Each shielding conductive line pattern SLp may extend in an eleventh direction Y4. Each shielding conductive line pattern SLp may be adjacent to each other in a tenth direction X4. The shielding conductive line pattern SLp may protrude from the shielding conductive plate SLh in a twelfth direction Z4. The shielding conductive line pattern SLp is directly connected to the shielding conductive plate SLh.

For example, the tenth direction X4 and the eleventh direction Y4 may be a horizontal direction that is horizontal to the substrate 100. The twelfth direction Z4 may be a vertical direction that is perpendicular to the substrate 100.

The shielding conductive plate SLh and each shielding conductive line pattern SLp may extend from the cell array region to the peripheral circuit region. A part of the shielding conductive pattern SL may be disposed on the peripheral circuit region, but is not limited thereto.

The shielding conductive pattern SL includes a conductive material. The shielding conductive pattern SL may include, for example, at least one of a conductive metal nitride, a conductive metal silicon nitride, a metal carbonitride, a conductive metal silicide, a conductive metal oxide, a two-dimensional material, and a metal.

The shielding insulating capping film 175 may be disposed on the substrate 100. For example, the shielding insulating capping film 175 may be disposed between the substrate 100 and the shielding conductive pattern SL.

The shielding insulating capping film 175 may come into contact with the shielding conductive pattern SL. In the semiconductor memory device according to some embodiments, the shielding insulating capping film 175 may come into contact with the shielding conductive plate SLh.

The shielding insulating liner 171 may be disposed on the shielding conductive pattern SL. The shielding insulating liner 171 may be disposed between the bit line BL and the substrate 100. The shielding insulating liner 171 may extend along the profiles of the shielding conductive plate SLh and the shielding conductive line pattern SLp.

Each of the shielding insulating liner 171 and the shielding insulating capping film 175 may be formed of an insulating material. When the shielding insulating liner 171 and the shielding insulating capping film 175 include the same material, a boundary between the shielding insulating liner 171 and the shielding insulating capping film 175 may not be distinguished.

Because the shielding structures 171, SL, and 175 are disposed between the bit lines BL adjacent to each other in the tenth direction X4, a coupling noise between the bit lines BL may be reduced.

Unlike the shown example, the semiconductor memory device according to some embodiments may not include the shielding conductive pattern SL.

The bit lines BL may be disposed on the substrate 100. For example, the bit lines BL may be disposed on the bonding insulating film 267.

The bit line BL may extend long in the eleventh direction Y4. Adjacent bit lines BL may be spaced apart from each other in the tenth direction X4. The bit line BL includes a long side wall extending in the eleventh direction Y4, and a short side wall extending in the tenth direction X4.

The bit line BL may be disposed on the shielding conductive pattern SL. The bit line BL may be disposed on the shielding conductive plate SLh.

The bit line BL may be disposed to be adjacent to the shielding conductive line pattern SLp. The bit line BL may be disposed to be adjacent to the shielding conductive line pattern SLp in the tenth direction X4. In other words, the shielding conductive line pattern SLp may extend in the eleventh direction Y4 along the long side wall of the bit line BL.

The bit line BL may be disposed between the shielding conductive line patterns SLp adjacent to each other in the tenth direction X4. The bit line BL may be disposed on the shielding insulating liner 171. For example, the shielding insulating liner 171 may come into contact with the bit line BL.

Although not shown, each bit line BL may extend from the cell array region to the peripheral circuit region. A part of each bit line BL may be disposed on the peripheral circuit region.

Each bit line BL may include a semiconductor pattern 161, a metal pattern 163, and a bit line mask pattern 165, which are stacked sequentially. Unlike the shown example, as an example, the bit line BL may include one of the semiconductor pattern 161 and the metal pattern 163. As another example, the bit line BL may not include the bit line mask pattern 165.

The bit line BL may include a conductive bit line. The conductive bit line includes a film of a conductive material in the bit line BL. The conductive bit line may include a semiconductor pattern 161 and a metal pattern 163.

The semiconductor pattern 161 may include a conductive semiconductor material. The conductive semiconductor material may be, for example, a semiconductor material doped with an impurity. The semiconductor pattern 161 may include at least one of polysilicon, polysilicon germanium, polygermanium, amorphous silicon, amorphous silicon germanium, and amorphous germanium.

The metal pattern 163 may include a conductive material including a metal. The metal pattern 163 may include, for example, at least one of a conductive metal nitride, a conductive metal silicon nitride, a metal carbonitride, a conductive metal silicide, a conductive metal oxide, a two-dimensional material, and a metal.

The bit line mask pattern 165 may include an insulating material. The bit line mask pattern 165 may include, but not limited to, silicon nitride, silicon oxynitride, or the like.

The first active patterns AP1 and the second active patterns AP2 may be disposed on each bit line BL. The first active patterns AP1 and the second active patterns AP2 may be disposed alternately along the eleventh direction Y4.

The first active patterns AP1 may be spaced apart from each other in the tenth direction X4. The first active patterns AP1 may be spaced apart at a constant interval. The second active patterns AP2 may be spaced apart from each other in the tenth direction X4. The second active patterns AP2 may be spaced apart at a constant interval. The first channel pattern AP1 may be spaced apart from the second channel pattern AP2 in the eleventh direction Y4. The first active patterns AP1 and the second active patterns AP2 may be arranged two-dimensionally along the tenth direction X4 and the eleventh direction Y4 that intersect each other. Each of the first channel pattern AP1 and the second channel pattern AP2 may be a channel region.

The back gate electrodes BG may be disposed on the bit line BL and the shielding conductive pattern SL. The back gate electrodes BG may be spaced apart from each other in the eleventh direction Y4. The back gate electrodes BG may be spaced apart at regular intervals. Each back gate electrode BG may extend in the tenth direction X4 across the bit line BL.

Each back gate electrode BG may be disposed between the first channel pattern AP1 and the second channel pattern AP2 adjacent to each other in the eleventh direction Y4. That is to say, the first channel pattern AP1 may be disposed on one side of each back gate electrode BG, and the second channel pattern AP2 may be disposed on the other side of each back gate electrode BG. Each back gate electrode BG may be disposed between the second side wall SS2 of the first channel pattern AP1 and the first side wall SS1 of the second channel pattern AP2. A height of the back gate electrode BG in the twelfth direction Z4 may be smaller than the heights of the first and second active patterns AP1 and AP2.

The first channel pattern AP1 may be disposed between the first word line WL1 and the back gate electrode BG. The second channel pattern AP2 may be disposed between the second word line WL2 and the back gate electrode BG. A pair of first word line WL1 and second word line WL2 may be disposed between the back gate electrodes BG adjacent to each other in the eleventh direction Y4.

The back gate isolation pattern 111 may be disposed between the first and second active patterns AP1 and AP2 adjacent to each other in the eleventh direction Y4. The back gate isolation pattern 111 may extend in the tenth direction X4 alongside the back gate electrode BG.

The back gate isolation pattern 111 may be made of an insulating material. The back gate isolation pattern 111 may include, but not limited to, a silicon oxide film, a silicon oxynitride film or a silicon nitride film.

The back gate insulating film 113 may be disposed between the back gate electrode BG and the first channel pattern AP1, and between the back gate electrode BG and the second channel pattern AP2. The back gate insulating film 113 may be disposed between the back gate electrode BG and the first channel pattern AP1, and between the back gate isolation pattern 111 and the second channel pattern AP2.

The back gate insulating film 113 may be made of an insulating material. The back gate insulating film 113 may include, but not limited to, silicon oxide.

The back gate capping pattern 115 may be disposed between the bit line BL and the back gate electrode BG. The back gate capping pattern 115 may be disposed between the first channel pattern AP1 and the second channel pattern AP2 adjacent to each other in the eleventh direction Y4. The back gate capping pattern 115 may extend in the tenth direction X4 alongside the back gate electrode BG.

The back gate capping pattern 115 may be made of an insulating material. The back gate capping pattern 115 may include, for example, but not limited to, at least one of a silicon oxide film, a silicon oxynitride film, and a silicon nitride film.

The first word line WL1 and the second word line WL2 may be disposed on the bit line BL and the shielding conductive pattern SL. Each of the first word line WL1 and the second word line WL2 may extend in the tenth direction X4. The first word line WL1 and the second word line WL2 may be arranged alternately in the eleventh direction Y4. The first active patterns AP1 and the second active patterns AP2 may be disposed between the first word line WL1 and the second word line WL2 that are adjacent to each other in the eleventh direction Y4.

In the semiconductor memory device according to some embodiments, the first word line WL1 and the second word line WL2 may be spaced apart from the bit line BL and the contact pattern BC in the twelfth direction Z4. The first word line WL1 and the second word line WL2 may be located between the bit line BL and the contact pattern BC.

Each of the first word line WL1 and the second word line WL2 may include a first portion WLa of the word line and a second portion WLb of the word line that are alternately disposed along the tenth direction X4. In the first word line WL1, each of the first active patterns AP1 may be disposed between the second portions WLb of the word line adjacent to each other in the tenth direction X4. In the second word line WL2, each second channel pattern AP2 may be disposed between the second portions WLb of the word lines adjacent to each other in the tenth direction X4.

The first word line WL1 and the second word line WL2 may include a conductive material. The first word line WL1 and the second word line WL2 may include at least one of, for example, a conductive semiconductor material, a conductive metal nitride, a conductive metal silicon nitride, a conductive metal carbonitride, a conductive metal silicide, a conductive metal oxide, a two-dimensional material, and a metal.

The gate insulating films GOX may be disposed between the first word line WL1 and the first channel pattern AP1, and between the second word line WL2 and the second channel pattern AP2. The gate insulating film GOX may extend in the tenth direction X4 alongside the first word line WL1 and the second word line WL2.

The gate insulating film GOX may be made of an insulating material. The gate insulating film GOX may include, for example, but not limited to, silicon oxide.

The gate isolation pattern GSS may be disposed on the bit line BL. The gate isolation pattern GSS may be disposed between the first word line WL1 and the second word line WL2 that are adjacent to each other in the eleventh direction Y4. The first word line WL1 and the second word line WL2 may be separated by the gate isolation pattern GSS. The gate isolation pattern GSS may extend in the tenth direction X4 between the first word line WL1 and the second word line WL2.

The gate isolation pattern GSS may be made of an insulating material. Although the gate isolation pattern GSS is shown as a single film, this is only for convenience of explanation, and the embodiment is not limited thereto. Unlike the shown example, the gate isolation pattern GSS may include a plurality of insulating films.

The contact patterns BC may penetrate the contact interlayer insulating film 231 and the contact etching stop film 212. The contact patterns BC may be connected to the first channel pattern AP1 and the second channel pattern AP2, respectively. The contact patterns BC correspond to the contact pattern BC shown in FIGS. 11 to 13, and may have the same characteristics as the contact pattern BC shown in FIGS. 11 to 13.

The contact etching stop film 212 may be disposed on the gate isolation pattern GSS and the back gate isolation pattern 111. Each of the contact interlayer insulating film 231 and the contact etching stop film 212 may be made of an insulating material.

The landing pads LP may be disposed on the contact pattern BC. From a planar viewpoint, the landing pads LP may have various shapes such as a circle, an ellipse, a rectangle, a square, a rhombus, and a hexagon.

The pad isolation insulation pattern 235 may be disposed between the landing pads LP. From the planar viewpoint, the landing pads LP may be arranged in the form of a matrix along the tenth direction X4 and the eleventh direction Y4. The upper surface of the landing pad LP may be substantially coplanar with the upper surface of the pad isolation insulation pattern 235, but is not limited thereto.

The landing pad LP includes a conductive material, and may include, for example, at least one of doped polysilicon, conductive metal nitride, conductive metal silicon nitride, metal carbonitride, conductive metal silicide, conductive metal oxide, two-dimensional material, and metal. Unlike the shown example, the semiconductor memory device according to some embodiments may not include the landing pad LP.

The data storage patterns DSP correspond to the data storage pattern DSP shown in FIGS. 11 to 13, and may have the same characteristics as the data storage pattern DSP shown in FIGS. 11 to 13. Each of the data storage patterns DSP may be disposed on the landing pads LP. The data storage patterns DSP may completely or partially overlap the landing pads LP in the twelfth direction Z4. The data storage patterns DSP may come into contact with all or a part of the upper surface of the landing pads LP.

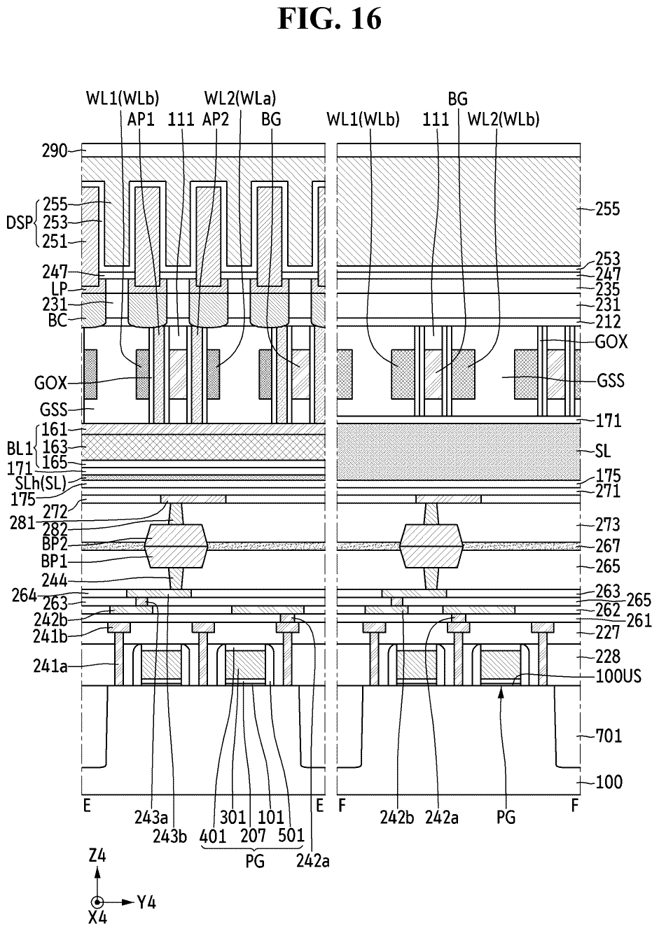

FIG. 16 is a diagram for explaining a semiconductor memory device according to another embodiment. For convenience of explanation, FIG. 16 will be mainly explained referring to the differences from the semiconductor device shown in FIGS. 14 and 15. For reference, FIG. 16 is a cross-sectional view taken along lines E-E and F-F of FIG. 14.

Referring to FIG. 16, the semiconductor memory device according to some embodiments may further include a peri-gate structure PG disposed between the substrate 100 and the bit line BL.

The peri-gate structure PG may be disposed on the substrate 100. For example, the peri-gate structure PG may be disposed on the upper surface 100US of the substrate. The peri-gate structure PG may be disposed across the cell array region and the peripheral circuit region. In other words, a part of the peri-gate structure PG may be disposed in the cell array region of the substrate 100, and the remainder of the peri-gate structure PG may be disposed in the peripheral circuit region of the substrate 100.

The peri-gate structure PG may correspond to the semiconductor device shown in FIGS. 1 to 4. That is, the peri-gate structure GS may include a gate interface film 101, a dielectric film structure 207, a gate electrode 301, a gate capping film 401, and a gate spacer 501.

The first-peri lower insulating film 227 and the second-peri lower insulating film 228 are disposed on the upper surface 100US of the substrate. Each of the first-peri lower insulating film 227 and the second-peri lower insulating film 228 includes an insulating material.

The peri-contact plug 241a and the peri-wiring line 241b may be disposed inside the first-peri lower insulating film 227 and the second-peri lower insulating film 228. The peri-contact plug 241a and the peri-wiring line 241b may be connected to the conductive patterns 223 and 225 of the peri-gate structure PG. Although not shown, the peri-contact plug 241a and the peri-wiring line 241b may be connected to the source/drain regions disposed on at least one side of the peri-gate structure PG.

Although the peri-contact plug 241a and the peri-wiring line 241b are shown to be different films from each other, the embodiment is not limited thereto. The boundary between the peri-contact plug 241a and the peri-wiring line 241b may not be distinguished. Each of the peri-contact plug 241a and the peri-wiring line 241b includes an insulating material.

The first peri-upper insulating film 261 and the second peri-upper insulating film 262 are disposed on the peri-contact plug 241a and the peri-wiring line 241b. Each of the first peri-upper insulating film 261 and the second peri-upper insulating film 262 includes an insulating material. It goes without saying that an insulating film formed of a single film may be disposed on the peri-contact plug 241a and the peri-wiring line 241b, unlike the shown example.

The first peri-connecting structures 242a and 242b may be connected to the peri-wiring line 241b. The first peri-connecting structures 242a and 242b may include a first peri-connecting via 242a and a first peri-connecting wiring 242b. Each of the first peri-connecting via 242a and the first peri-connecting wiring 242b includes a conductive material. Although the first peri-connecting via 242a and the first peri-connecting wiring 242b are shown as being different films from each other, the embodiment is not limited thereto.

The third peri-upper insulating film 263 and the fourth peri-upper insulating film 264 may be disposed on the first peri-connecting structures 242a and 242b. Each of the third peri-upper insulating film 263 and the fourth peri-upper insulating film 264 includes an insulating material. It goes without saying that an insulating film made of a single film may be disposed on the first peri-connecting structures 242a and 242b, unlike the shown example.

The second peri-connecting structures 243a and 243b may be connected to the first peri-connecting wiring 242b. The second peri-connecting structures 243a and 243b may include a second peri-connecting via 243a and a second peri-connecting wiring 243b. Each of the second peri-connecting via 243a and the second peri-connecting wiring 243b includes a conductive material. Although the second peri-connecting via 243a and the second peri-connecting wire 243b are shown to be different films from each other, the embodiment is not limited thereto.

The first peri-connecting structures 242a and 242b and the second peri-connecting structures 243a and 243 are shown to be disposed on the peri-gate structure PG, but the embodiment is not limited thereto. It goes without saying that only one peri-connecting structure may be disposed on the peri-gate structure PG, unlike the shown example.

A fifth peri-upper insulating film 265 may be disposed on the second peri-connecting structures 243a and 243b. The fifth peri-upper insulating film 265 includes an insulating material.

A lower bonding pad BP1 may be disposed on the peri-gate structure PG. The lower bonding pad BP1 may be connected to the second peri-connecting structures 243a and 243b.

For example, at least one of the lower bonding pads BP1 may be connected to the peri-gate structure PG. At least the other of the lower bonding pads BP1 may be connected to a source/drain region disposed on at least one side of the peri-gate structure PG.

The lower pad plug 244 may connect the lower bonding pad BP1 and the second peri-connecting wiring 243b. The lower bonding pad BP1 and the lower pad plug 244 may be disposed inside the fifth peri-upper insulating film 265.

A first cell lower insulating film 271, a second cell lower insulating film 272, and a third cell lower insulating film 273 may be disposed on the fifth peri-upper insulating film 265. The first cell lower insulating film 271, the second cell lower insulating film 272, and the third cell lower insulating film 273 may be disposed on the lower bonding pad BP1.

The second cell lower insulating film 272 may be disposed between the first cell lower insulating film 271 and the third cell lower insulating film 273. The first cell lower insulating film 271 may be disposed between the second cell lower insulating film 272 and the fifth peri-upper insulating film 265. Each of the first cell lower insulating film 271, the second cell lower insulating film 272, and the third cell lower insulating film 273 includes an insulating material.

An upper bonding pad BP2 may be disposed on the lower bonding pad BP1. The upper bonding pad BP2 may be disposed on the fifth peri-upper insulating film 265.

The upper bonding pad BP2 may be connected to a lower bonding pad BP1. The upper bonding pad BP2 may come into contact with the lower bonding pad BP1.

A cell connecting wiring 281 may be disposed on the upper bonding pad BP2. The cell connecting wiring 281 may be disposed between the upper bonding pad BP2 and the bit line BL. The cell connecting wiring 281 may be disposed between the upper bonding pad BP2 and the shielding conductive pattern SL.

Although not shown, the cell connecting wiring 281 may be connected to at least one of the bit line BL and the shielding conductive pattern SL.

Although the cell connecting wiring 281 disposed on one metal level is shown to be disposed between the upper bonding pad BP2 and the bit line BL, this is only for convenience of explanation, and the embodiment is not limited thereto. A plurality of cell connecting wirings 281 disposed at different metal levels from each other may be disposed between the upper bonding pad BP2 and the bit line BL.

The upper pad plug 282 may connect the upper bonding pad BP2 and the cell connecting wiring 281. The upper bonding pad BP2 may be connected to the cell connecting wiring 281 through the upper pad plug 282.

The upper bonding pad BP2 and the upper pad plug 282 may be disposed inside the third cell lower insulating film 273. The cell connecting wiring 281 may be disposed inside the second cell lower insulating film 272.

The upper pad plug 282 and the lower pad plug 244 may include a conductive material including a metal. Each of the lower bonding pad BP1 and the upper bonding pad BP2 may include a conductive material including a metal. The cell connecting wiring 281 may include a conductive material including a metal.

Although each of the lower bonding pad BP1 and the upper bonding pad BP2 is shown as being a single film, this is only for convenience of explanation, and the embodiment is not limited thereto. Although each of the upper pad plug 282 and the lower pad plug 244 is shown to be a single film, but the embodiment is not limited thereto. Although the cell connecting wiring 281 is shown as being a single film, the embodiment is not limited thereto.

The shielding conductive pattern SL and the bit line BL may be disposed on the peri-gate structure PG. The shielding conductive pattern SL and the bit line BL may be disposed on the upper bonding pad BP2. For example, the shielding conductive pattern SL and the bit line BL may be disposed on the cell connecting wiring 281.

The first cell lower insulating film 271 may be disposed between the bit line BL and the cell connecting wiring 281, and between the shielding conductive pattern SL and the cell connecting wiring 281. The first cell lower insulating film 271 may be disposed between the shielding insulating liner 171 and the second cell lower insulating film 272, and between the shielding insulating capping film 175 and the second cell lower insulating film 272.

A cell upper insulating film 290 may be disposed on the data storage pattern DSP. The cell upper insulating film 290 includes an insulating material.

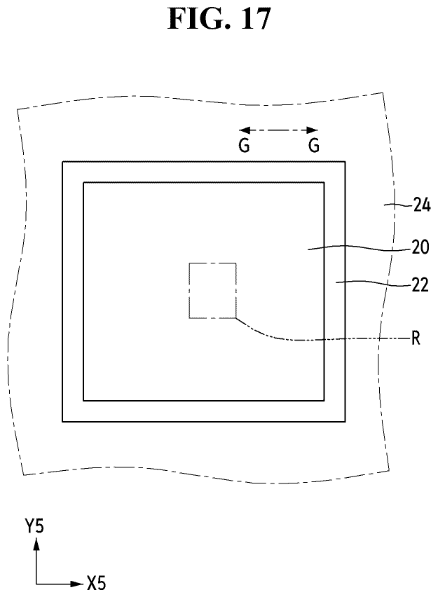

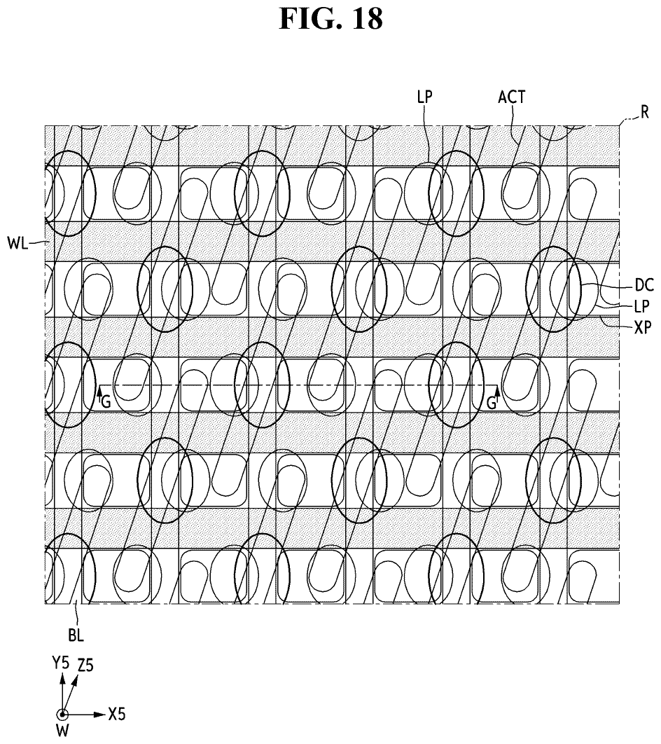

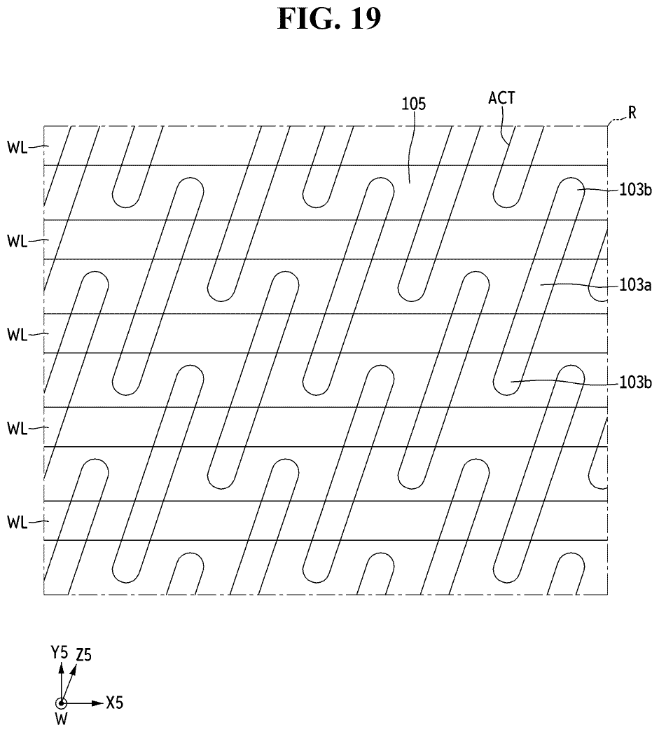

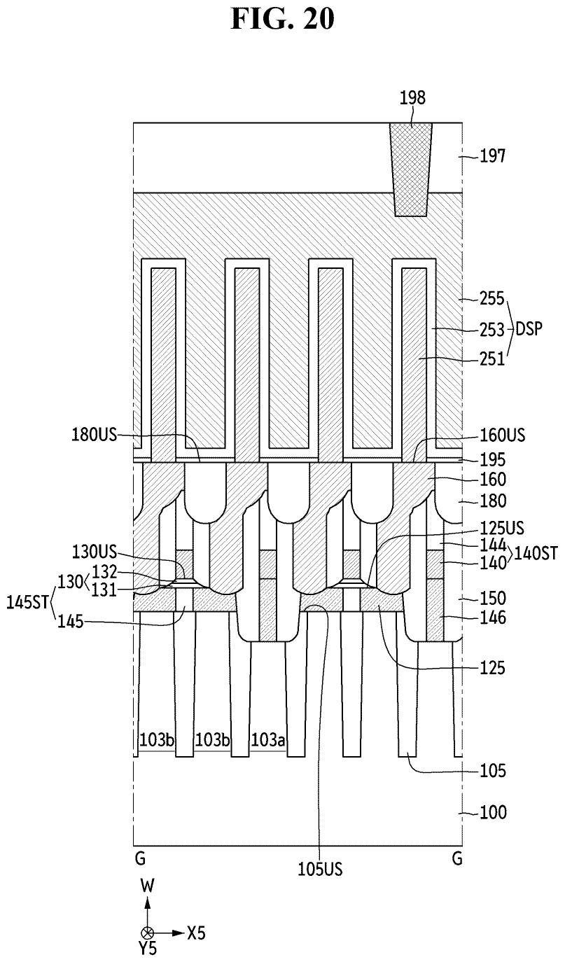

FIG. 17 is a schematic layout diagram of a semiconductor memory device according to some embodiments. FIG. 18 is a layout of a region R that is a part of the cell region of FIG. 17. FIG. 19 is a layout showing only the word line and the active region of FIG. 18. FIG. 20 is a cross-sectional view taken along G-G of FIG. 18. For convenience of explanation, differences from the semiconductor device shown in FIGS. 15 and 16 will be mainly described in FIGS. 17 to 20.

For reference, in FIG. 17, the cutting line G-G is shown to be taken along a thirteenth direction X5, but the embodiment is not limited thereto. Unlike the shown example, the cutting line G-G may be shown as being taken along a fourteenth direction Y5. In the diagrams relating to the semiconductor memory device according to some embodiments, a dynamic random access memory (DRAM) is shown as an example, but the embodiment is not limited thereto.

Referring to FIGS. 17 to 20, the semiconductor memory device according to some embodiments may include a cell region 20, a cell region element isolation film 22, and a peri-region 24.

The cell region element isolation film 22 may be formed along the periphery of the cell region 20. The cell region element isolation film 22 may separate the cell region 20 from the peri-region 24. The peri-region 24 may be defined around the cell region 20. The cell region 20 may include a plurality of cell active regions ACT. As the design rule of the semiconductor memory device decreases, the cell active regions ACT may be disposed in the form of a bar of a diagonal line or an oblique line, as shown. For example, the cell active regions ACT may extend in a fifteenth direction Z5.

A plurality of gate electrodes may be disposed in a thirteenth direction X5 across the cell active regions ACT. The plurality of gate electrodes may extend to be parallel to each other. The plurality of gate electrodes may be, for example, a plurality of word lines WL. The word lines WL may be disposed at equal intervals. A width of the word line WL or an interval between the word lines WL may be determined depending on a design rule.

Each cell active region ACT may be divided into three portions by the two word lines WL extending in the thirteenth direction X5. The cell active region ACT may include a bit line connecting region 103a and a storage connecting region 103b. The bit line connecting region 103a may be located at a central portion of the cell active region ACT, and the storage connecting region 103b may be located at an end portion of the cell active region ACT.

For example, the bit line connecting region 103a may be a region connected to the bit line BL, and the storage connecting region 103b may be a region connected to the data storage pattern DSP. In other words, the bit line connecting region 103a may correspond to a common drain region, and the storage connecting region 103b may correspond to a source region. Each word line WL, and the bit line connecting region 103a and the storage connecting region 103b adjacent thereto may form a transistor.

A plurality of bit lines BL extending in the fourteenth direction Y5 perpendicular to the word lines WL may be disposed on the word lines WL. The plurality of bit lines BL may extend to be parallel to each other. The bit lines BL may be disposed at equal intervals. The width of the bit lines BL or the interval between the bit lines BL may be determined depending on a design rule.

The fourth direction W may be perpendicular to the thirteenth direction X5, the fourteenth direction Y5, and the fifteenth direction Z5. The fourth direction W may be a thickness direction of the substrate 100.

The semiconductor memory device according to some embodiments may include various contact arrangements formed on the cell active region ACT. The various contact arrangements may include, for example, a direct contact DC, a node pad XP, a landing pad LP, and the like.

Here, the direct contact DC may mean a contact that electrically connects the cell active region ACT to the bit line BL. The node pad XP may be a connecting pad that connects the cell active region ACT to the lower electrode 251 of the capacitor. Due to the layout structure, a contact area between the node pad XP and the cell active region ACT may be small. Therefore, a conductive landing pad LP may be introduced to enlarge the contact area with the cell active region ACT and enlarge the contact area with the lower electrode 251 of the capacitor.

The landing pad LP may be disposed between the node pad XP and the lower electrode 251 of the capacitor. By enlarging the contact area through the introduction of the landing pad LP, the contact resistance between the cell active region ACT and the lower electrode 191 of the capacitor may decrease.

The direct contact DC may be connected to the bit line connecting region 103a. The node pad XP may be connected to the storage connecting region 103b.

As the node pad XP is disposed at both end portions of the cell active region ACT, the landing pad LP may be disposed to be adjacent to both ends of the cell active region ACT to at least partially overlap the node pad XP.

The word line WL may be formed as a structure buried in the substrate 100. The word line WL may be disposed across the cell active region ACT between the direct contact DC and the node pad XP. As shown, two word lines WL may be disposed to intersect one cell active region ACT. As the cell active region ACT extends along the fifteenth direction Z5, the word lines WL may have an angle of less than 90 degrees with the cell active region ACT.

The direct contact DC and the node pad XP may be disposed symmetrically. Accordingly, the direct contact DC and the node pad XP may be disposed on a straight line along the thirteenth direction X5 and the fourteenth direction Y5. Meanwhile, unlike the direct contact DC and the node pad XP, the landing pad LP may be disposed in zigzags in the fourteenth direction Y5 in which the bit line BL extends. Also, the landing pad LP may be disposed to overlap the same side surface portions of each bit line BL in the thirteenth direction X5 in which the word lines WL extend.

The semiconductor memory device according to another embodiment of the present disclosure may include a plurality of bit line structures 140ST, a plurality of node connecting pads 125, a plurality of bit line contacts 146, and an information storage unit DSP.

The cell element isolation film 105 may be formed inside the substrate 100. The cell element isolation film 105 may have a shallow trench isolation (STI) structure having excellent isolation characteristics. The cell element isolation film 105 may define a cell active region ACT inside the memory cell region.

The cell active region ACT defined by the cell element separation film 105 may have a long island formation including a short axis and a long axis. The cell active region ACT may have an oblique line shape to have an angle of less than 90 degrees with respect to the word line WL3 formed inside the cell element separation film 105. Also, the cell active region ACT may have an oblique line shape to have an angle of less than 90 degrees with respect to the bit line BL formed on the cell element separation film 105.

The cell element isolation film 105 may include, but not limited to, at least one of, for example, a silicon oxide film, a silicon nitride film, and a silicon oxynitride film.

Although the cell element isolation film 105 is shown as being formed of a single insulating film, this is only for convenience of explanation, and the embodiment is not limited thereto. Depending on the spaced distance between adjacent cell active regions ACT, the cell element isolation film 105 may be formed of one insulating film or may be formed of a plurality of insulating films.

Although the upper surface 105US of the cell element isolation film and the upper surface of the substrate 100 are shown as being disposed on the same plane, this is only for convenience of explanation, and the embodiment is not limited thereto.

In FIG. 20, when a transistor including each word line WL, and the bit line connecting region 103a and the storage connecting region 103b adjacent thereto is an NMOS, the storage connecting region 103b and the bit line connecting region 103a may include at least one of doped n-type impurities, for example, phosphorus (P), arsenic (As), antimony (Sb), and bismuth (Bi). When the transistor including each word line WL, and the bit line connecting region 103a and the storage connecting region 103b adjacent thereto is a PMOS, the storage connecting region 103b and the bit line connecting region 103a may include doped p-type impurities, for example, boron (B).

The bit line structure 140ST may include a cell conductive line 140 and a cell line capping film 144. The cell conductive line 140 may be disposed on the substrate 100 on which the cell gate structure 110 is formed, and the cell element isolation film 105. The cell conductive line 140 may intersect the cell element isolation film 105, and the cell active region ACT defined by the cell element isolation film 105. The cell conductive line 140 may be formed to intersect the cell gate structure 110. Here, the cell conductive line 140 may correspond to the bit line BL.

The cell conductive line 140 may include, for example, at least one of a semiconductor material doped with impurities, a conductive metal silicide, a conductive metal nitride, a conductive metal oxide, a two-dimensional material (2D material), a metal, and a metal alloy.

Although the cell conductive line 140 is shown as being a single film, this is only for convenience of explanation, and the embodiment is not limited thereto. That is, unlike the shown example, the cell conductive line 140 may include a plurality of conductive layers in which the conductive materials are stacked.

The cell line capping film 144 may be disposed on the cell conductive line 140. The cell line capping film 144 may extend in the fourteenth direction Y5 along the upper surface of the cell conductive line 140. The cell line capping film 144 may include, for example, at least one of a silicon nitride film, a silicon oxynitride, a silicon carbonitride, and a silicon oxycarbonitride.

In the semiconductor memory device according to some embodiments, the cell line capping film 144 may include a silicon nitride film. Although the cell line capping film 144 is shown as being a single film, the embodiment is not limited thereto.

The bit line contact 146 may be formed between the cell conductive line 140 and the substrate 100. The cell conductive line 140 may be disposed on the bit line contact 146.

The bit line contact 146 may be disposed between the cell conductive line 140 and the substrate 100. The cell conductive line 140 may be disposed on the bit line contact 146. The bit line contact 146 may be formed between the bit line connecting region 103a of the cell active region ACT and the cell conductive line 140. The bit line contact 146 may be connected to the bit line connecting region 103a.

The bit line contact 146 may have a circular or elliptical shape from a planar viewpoint. The plane area of the bit line contact 146 may be larger than the area in which the bit line connecting region 103a and one cell conductive line 140 overlap. The plane area of the bit line contact 146 may be larger than the plane area of one bit line connecting region 103a.

The bit line contact 146 may electrically connect the cell conductive line 140 and the substrate 100. Here, the bit line contact 146 may correspond to a direct contact DC. The bit line contact 146 may include, for example, at least one of an impurity-doped semiconductor material, a conductive metal silicide, a conductive metal nitride, a conductive metal oxide, a metal, and a metal alloy.

A node connecting pad 125 may be disposed on the substrate 100. The node connecting pad 125 may be disposed on the storage connecting region 103b of the cell active region ACT. The node connecting pad 125 is connected to the storage connecting region 103b.

The node connecting pad 125 may be disposed between the cell conductive lines 140 adjacent to each other in the thirteenth direction X5. Although not shown, the node connecting pad 125 may be disposed between the cell gate electrodes 112 adjacent to each other in the fourteenth direction Y5.

The node connecting pad 125 may electrically connect the information storage unit DSP and the substrate 100. Here, the node connecting pad 125 may correspond to the node pad XP.

The node connecting pad 125 may include at least one of, for example, a semiconductor material doped with impurities, a conductive metal silicide, a conductive metal nitride, a conductive metal oxide, a metal, and a metal alloy.

A pad isolation structure 145ST may separate the node connecting pads 125 adjacent to each other in the thirteenth direction X5. Although not shown, the pad isolation structure 145ST may separate the node connecting pads 125 adjacent to each other in the fourteenth direction Y5. The pad isolation structure 145ST covers the upper surface 125US of the node connecting pad.

The pad isolation structure 145ST may include a pad isolation pattern 145 and an upper cell insulating film 130. The upper cell insulating film 130 may be disposed on the pad isolation pattern 145.

When the node connecting pad 125 includes a first node connecting pad and a second node connecting pad that are spaced apart in the thirteenth direction X5, the pad isolation pattern 145 may separate the first node connecting pad and the second node connecting pad in the thirteenth direction X5. Although not shown, the pad isolation pattern 145 may also separate the node connecting pad 125 adjacent to each other in the fourteenth direction Y5.

The upper cell insulating film 130 covers the upper surface 125US of the node connecting pad. When the node connecting pad 125 includes a first node connecting pad and a second node connecting pad that are spaced apart in the thirteenth direction X5, the upper cell insulating film 130 may cover the upper surface of the first node connecting pad and the upper surface of the second node connecting pad.

The pad isolation pattern 145 and the upper cell insulating film 130 may be disposed between the bit line contacts 146 adjacent to each other in the fourteenth direction Y5. The cell conductive line 140 may be disposed on the upper surface of the pad isolation structure 145ST. The cell conductive line 140 may be disposed on the upper surface 130US of the upper cell insulating film. The upper surface of the pad isolation structure 145ST may be the upper surface 130US of the upper cell insulating film.

The pad isolation pattern 145 may include, for example, at least one of silicon nitride (SiN), silicon oxynitride (SiON), silicon oxide (SiO₂), silicon carbonitride (SiCN), silicon oxycarbonitride (SiOCN), and combinations thereof. Although the upper cell insulating film 130 may be a single film, the upper cell insulating film 130 may be a multi-layer film that includes a first upper cell insulating film 131 and a second upper cell insulating film 132, as shown. For example, the first upper cell insulating film 131 may include a silicon oxide film, and the second upper cell insulating film 132 may include a silicon nitride film, but the embodiment is not limited thereto. The width of the upper cell insulating film 130 in the thirteenth direction X5 is shown to decrease as it goes away from the substrate 100, but the embodiment is not limited thereto.

In the portion of the cell conductive line 140 in which the bit line contact 146 is formed, the bit line spacer 150 may be disposed on the side walls of the cell conductive line 140, the cell line capping film 144, and the bit line contact 146. In the remaining portions of the cell conductive lines 140 in which the bit line contact 146 is not formed, bit line spacers 150 may be disposed on the upper cell insulating film 130.

Although the bit line spacer 150 is shown as being a single film, this is only for convenience of explanation, and the embodiment is not limited thereto. In other words, unlike the shown example, it goes without saying that the bit line spacer 150 has a multi-layer film structure. The bit line spacer 150 may include, for example, but not limited to, one of a silicon oxide film, a silicon nitride film, a silicon oxynitride film (SiON), a silicon oxycarbonitride film (SiOCN), air, and combinations thereof.

A storage pad 160 may be disposed on each node connecting pad 125. The storage pad 160 may be electrically connected to the node connecting pad 125. The storage pad 160 may be connected to the storage connecting region 103b of the cell active region ACT. Here, the storage pad 160 may correspond to the landing pad LP.

In the semiconductor memory device according to some embodiments, the storage pad 160 may extend to the node connecting pad 125, and be connected to the node connecting pad 125. The storage pad 160 may overlap a part of the upper surface of the bit line structure 140ST.

The storage pad 160 may include at least one of, for example, a semiconductor material doped with impurities, a conductive metal silicide, a conductive metal nitride, a conductive metal carbide, a conductive metal oxide, a metal, and a metal alloy.

A pad isolation insulating film 180 may be formed on the storage pad 160 and the bit line structure 140ST. For example, the pad isolation insulating film 180 may be disposed on the cell line capping film 144. The pad isolation insulating film 180 may define the storage pad 160 that forms a plurality of isolation regions.

The pad isolation insulating film 180 may include an insulating material, and may electrically separate the plurality of storage pads 160 from each other. For example, the pad isolation insulating film 180 may include, for example, but not limited to, at least one of a silicon oxide film, a silicon nitride film, a silicon oxynitride film, a silicon oxycarbonitride film, and a silicon carbonitride film.

A first etching stop film 195 may be disposed on the storage pad 160 and the pad isolation insulating film 180. The first etching stop film 195 may include at least one of a silicon nitride film, a silicon carbonitride film, a silicon boron nitride film (SiBN), a silicon oxynitride film, and a silicon oxycarbide film.

The data storage pattern DSP corresponds to the data storage pattern DSP shown in FIGS. 11 to 13, and may have the same characteristics as the data storage pattern DSP shown in FIGS. 11 to 13.

An interlayer insulating film 197 is disposed on the plate electrode 255. The interlayer insulating film 197 may include, for example, at least one of silicon oxide, silicon nitride, silicon oxynitride, and a low dielectric constant material. The low dielectric constant material may include, for example, but not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

A contact plug 198 may be disposed inside the interlayer insulating film 197. The contact plug 198 is electrically connected to the upper plate electrode 194. A part of the contact plug 198 may enter inside of the upper plate electrode 194.

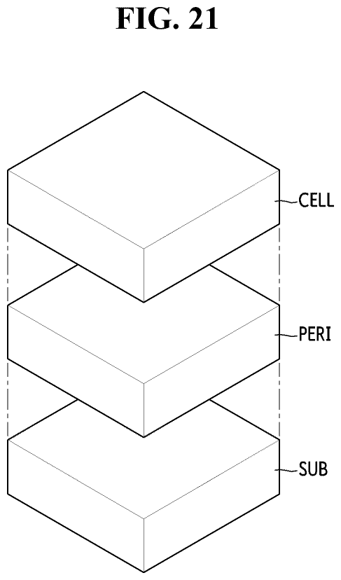

FIG. 21 is a diagram for illustrating a semiconductor memory device according to some implementations.

Referring to FIG. 21, the semiconductor memory device according to some embodiments may have a COP (Cell on Peri) structure in which the cell array region CA is disposed on the peri-structure region PA.

For example, the cell array region CELL may include a vertical channel transistor VCT of FIGS. 11 to 13. A sensing transistor, a transfer transistor, a driving transistor, and the like connected to the vertical channel transistor of FIGS. 11 to 13 may be disposed in the peri-structure region PERI.

As another example, the cell array region CELL may include the vertical channel transistor VCT of FIGS. 14 and 15. The sensing transistor, the transfer transistor, the driving transistor, and the like connected to the vertical channel transistor of FIGS. 14 and 15 may be disposed in the peri-structure region PERI.

As another example, the cell array region CELL may include the vertical channel transistor VCT of FIG. 16. The sensing transistor, the transfer transistor, the driving transistor, and the like connected to the vertical channel transistor of FIG. 16 may be disposed in the peri-structure region PERI.

As another example, the cell array region CELL may include a plurality of buried contacts BC of FIGS. 17 to 20. The sensing transistor, the transfer transistor, the driving transistor, and the like connected to the transistor including the buried contact of FIGS. 17 to 20 may be disposed in the peri-structure region PERI.

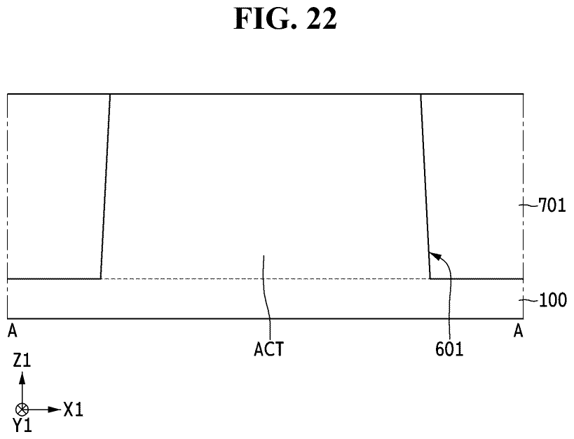

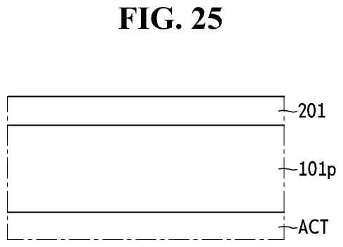

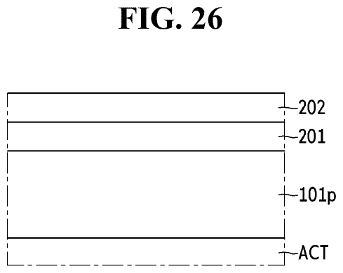

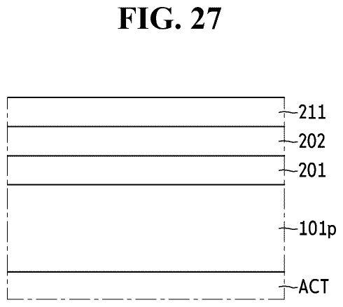

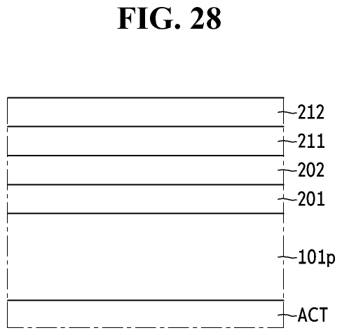

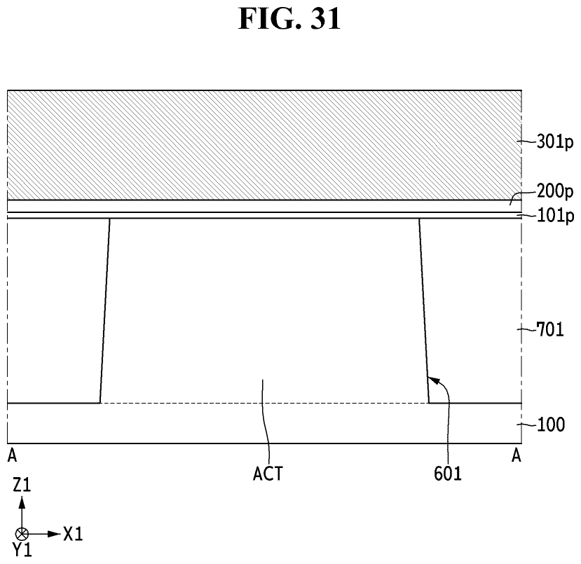

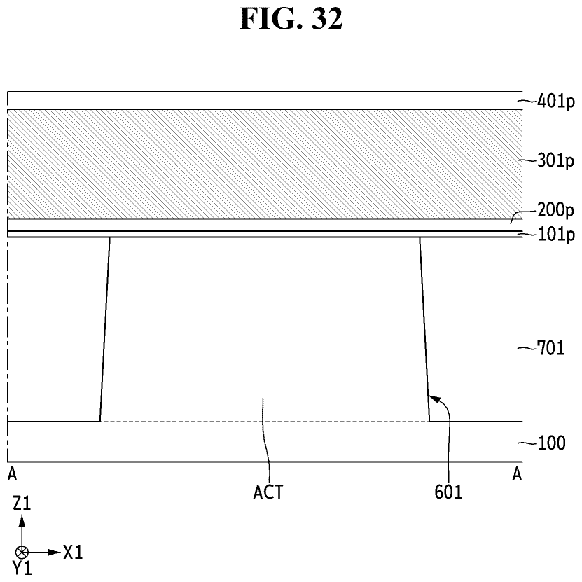

FIGS. 22 to 38 are intermediate stage diagrams for explaining a method for manufacturing a semiconductor memory device according to some embodiments.

First, referring to FIG. 22, a substrate 100 may be provided. A trench 601 may be formed inside the substrate 100. The trench 601 may define an active region. An element isolation film 701 may be formed inside the trench 601.

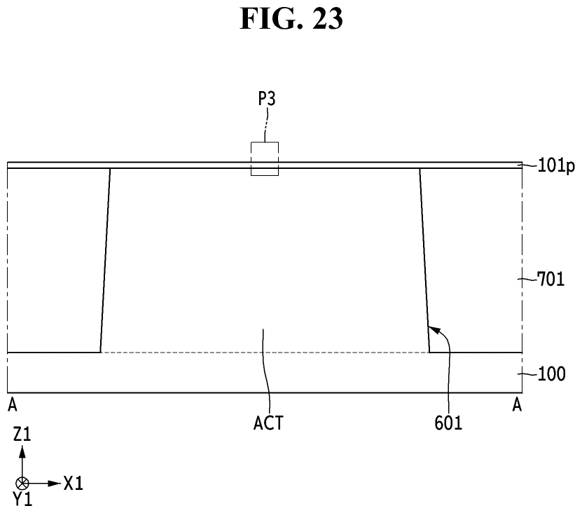

Referring to FIG. 23, a pre-gate interface film 101P may be formed on the substrate 100. The pre-gate interface film 101P may extend along an upper surface of the element isolation film 701 and an upper surface of the active region ACT. The pre-gate interface film 101P may be formed to have a certain thickness. The pre-gate interface film 101P may include, for example, silicon oxide, silicon oxynitride or a combination thereof.

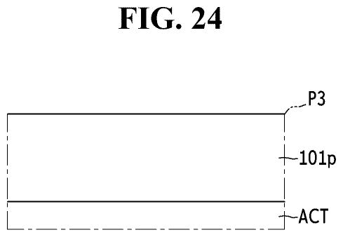

For reference, FIGS. 24 to 29 are enlarged views of a region P3 of FIG. 23. Hereinafter, for convenience of explanation, the enlarged views of the region P3 of FIG. 23 will be described.

Referring to FIGS. 24 to 29, a first pre-dielectric film structure 200p in which a first dielectric film 201, a second dielectric film 202, a third dielectric film 211, a fourth dielectric film 212, a fifth dielectric film 213, and a sixth dielectric film 214 are sequentially stacked may be formed on the pre-gate interface film 101P. The first to sixth dielectric films 201, 202, 211, 212, 213, and 214 may be sequentially stacked, but not limited to, by an atomic layer deposition (ALD) method. As another example, the first to sixth dielectric films 201, 202, 211, 212, 213, and 214 may be sequentially stacked by a chemical vapor deposition (CVD) method and a physical vapor deposition (PVD) method.

The materials for forming the first dielectric film 201, the third dielectric film 211, and the fifth dielectric film 213 may have higher dielectric constant than the materials for forming the second dielectric film 202, the fourth dielectric film 212, and the sixth dielectric film 216. For example, the first dielectric film 201, the third dielectric film 211, and the fifth dielectric film 213 may include, but not limited to, hafnium oxide (HfO). The second dielectric film 202, the fourth dielectric film 212, and the sixth dielectric film 216 may include, but not limited to, silicon oxide (SiO).

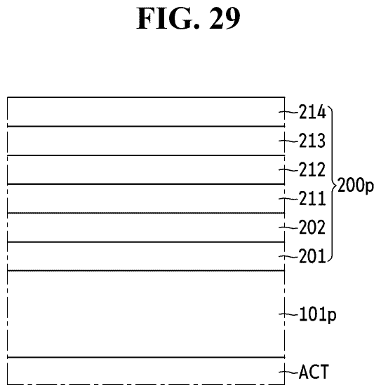

Although FIG. 29 shows a case where the first pre-dielectric film structure 200p includes six dielectric films 201, 202, 211, 212, 213, and 214, the embodiment is not limited thereto. As another example, the first pre-dielectric film structure 200p may be made up of eight or more dielectric films.

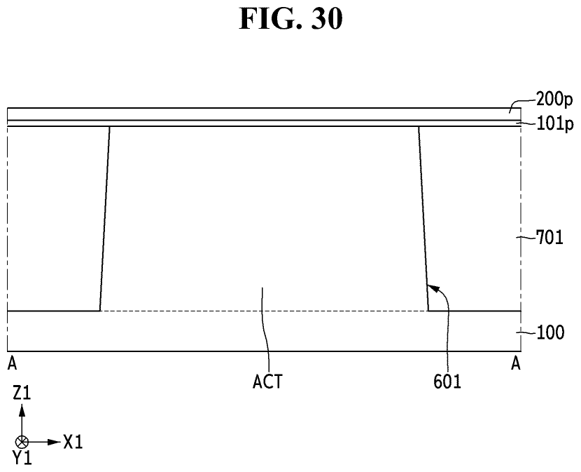

Next, referring to FIGS. 30 to 32, a pre-gate electrode 301p and a pre-gate capping film 401p may be sequentially stacked on the first pre-dielectric film structure 200p.

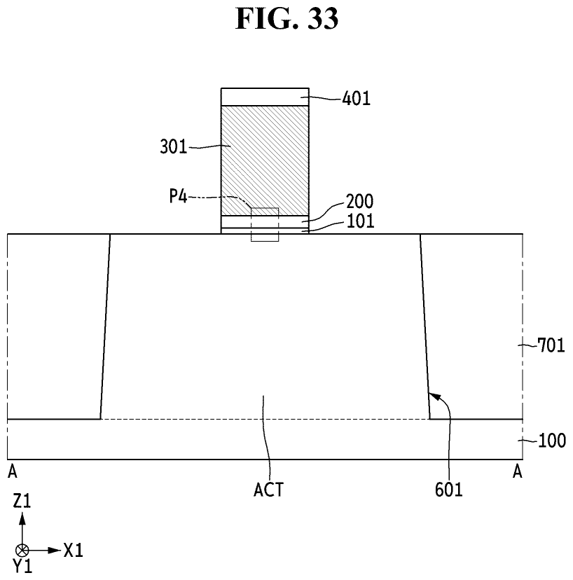

Referring to FIG. 33, the pre-gate interface film 101P, the first pre-dielectric film structure 200p, the pre-gate electrode 301p, and the pre-gate capping film 401p may be patterned to form the gate interface film 101, the second pre-dielectric film structure 200, the gate electrode 301, and the gate capping film 401.

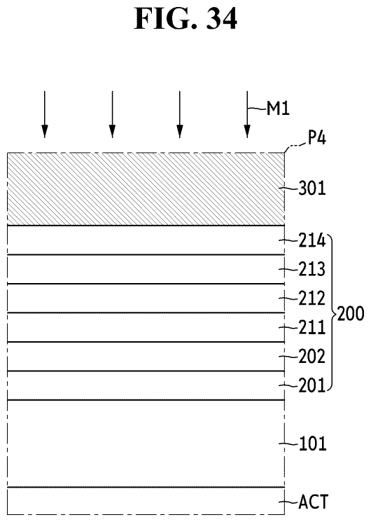

FIGS. 34 to 36 are enlarged views of a region P4 of FIG. 33. Hereinafter, the enlarged view of the region P4 of FIG. 33 will be described for convenience of explanation.

Referring to FIG. 34, impurities M1 may be injected into the second pre-dielectric film structure 200. The impurities may include, for example, nitrogen. The process of injecting the impurities M1 may be, for example, a rapid thermal nitridation (RTN) process. Since the second pre-dielectric film structure 200 includes a plurality of films in which dielectric films including different materials from each other are alternately stacked, a dangling bond may be easily formed. Nitrogen may be easily injected by such a dangling bond. The concentration of nitrogen that is present in the second pre-dielectric film structure 200 may be adjusted by alternately stacking dielectric films including different materials from each other.

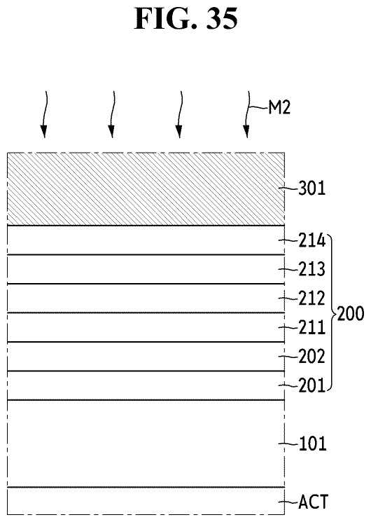

Referring to FIG. 35, a heat treatment process M2 may be performed on the gate interface film 101, the second pre-dielectric film structure 200, the gate electrode 301, and the gate capping film 401. The heat treatment process M2 may include, for example, an annealing process.

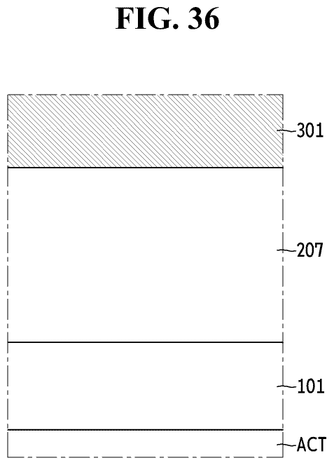

Next, referring to FIG. 36, a dielectric film structure 207 may be formed by a heat treatment process (see M2 of FIG. 35). That is to say, a single film may be formed by performing the heat treatment process M2 on the second pre-dielectric film structure 200 including a plurality of layers. The dielectric film structure 207 may include, for example, hafnium silicon oxynitride.

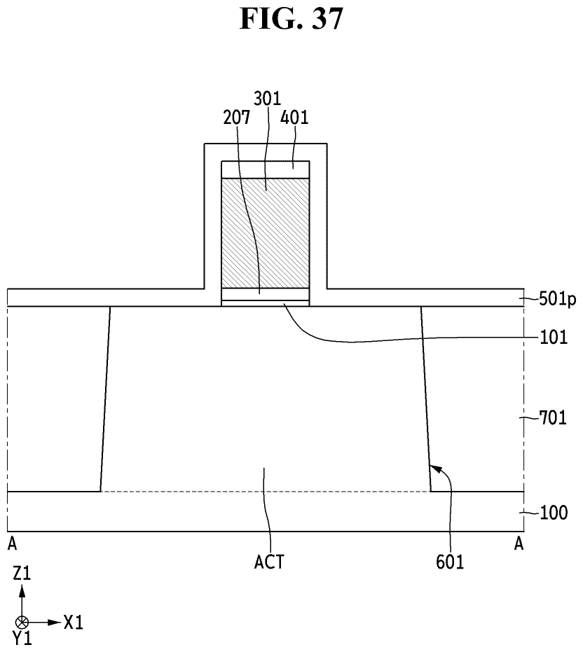

Referring to FIG. 37, a pre-gate spacer 501p may be formed. The pre-gate spacer 501p may be formed along the upper surface of the element isolation film 701, the upper surface of the gate capping film 401, and the side walls of the gate interface film 101, the dielectric film structure 207, the gate electrode 301 and the gate capping film.

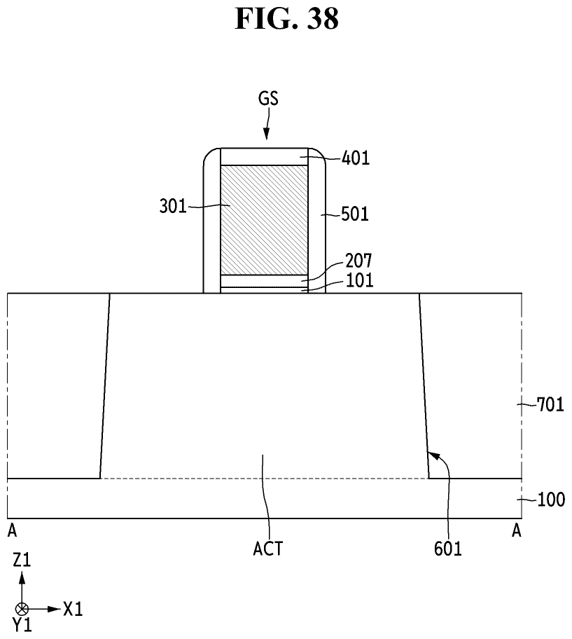

Next, referring to FIG. 38, the pre-gate spacer 501p may be patterned to form a gate spacer 501.

Next, referring to FIG. 2, a source/drain pattern SDR is formed in the active region ACT of the substrate 100. The source/drain pattern SDR may be formed by injecting impurities into the front surface of the substrate 100.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor device comprising:
a substrate;
an active region disposed on or in the substrate;
a gate interface film which is in contact with the active region;
a dielectric film structure which is disposed on the gate interface film, and includes a metal silicon oxide;
a gate electrode on the dielectric film structure; and
a source/drain pattern which is disposed on both sides of the gate electrode,
wherein the dielectric film structure includes an impurity element doped to the metal silicon oxide,
the dielectric film structure includes a first dielectric film region and a second dielectric film region, and
a concentration of silicon of the first dielectric film region is greater than the concentration of silicon of the second dielectric film region.

2. The semiconductor device of claim 1,
wherein the concentration of the impurity element of the first dielectric film region is greater than the concentration of the impurity element of the second dielectric film region.

3. The semiconductor device of claim 1,
wherein the impurity element includes nitrogen.

4. The semiconductor device of claim 1,
wherein the first dielectric film region is disposed between the second dielectric film region and the gate interface film.

5. The semiconductor device of claim 1,
wherein the second dielectric film region is disposed between the first dielectric film region and the gate interface film.

6. The semiconductor device of claim 1,
wherein the dielectric film structure further includes a third dielectric film region,
the concentration of silicon of the third dielectric film region is greater than the concentration of silicon of the second dielectric film region, and
the second dielectric film region is disposed between the first dielectric film region and the third dielectric film region.

7. The semiconductor device of claim 1,
wherein the dielectric film structure further includes a third dielectric film region,
the concentration of silicon of the third dielectric film region is smaller than the concentration of silicon of the first dielectric film region, and
the first dielectric film region is disposed between the second dielectric film region and the third dielectric film region.

8. The semiconductor device of claim 1,
wherein the metal silicon oxide includes at least one of hafnium (Hf), lanthanum (La), zirconium (Zr) and aluminum (Al).

9. The semiconductor device of claim 1,
wherein the gate interface film includes silicon oxide.

10. A semiconductor device comprising:
a substrate;
an active region disposed on or in the substrate;
a gate interface film which is in contact with the active region;
a dielectric film structure which is disposed on the gate interface film, and includes a metal silicon oxide;
a gate electrode on the dielectric film structure; and
a source/drain pattern which is disposed on both sides of the gate electrode,
wherein the dielectric film structure includes an impurity element doped to the metal silicon oxide,
the dielectric film structure includes a first surface and a second surface that are opposite to each other in one direction, and
the dielectric film structure includes a portion in which the concentration of silicon increases and then decreases, as a distance from the portion to the first surface of the dielectric film structure increases.

11. The semiconductor device of claim 10,
wherein the first surface of the dielectric film structure is in contact with the gate interface film.

12. The semiconductor device of claim 10,
wherein the first surface of the dielectric film structure is in contact with the gate electrode.

13. The semiconductor device of claim 10,
wherein the concentration of silicon in the dielectric film structure increases, decreases, and then increases again, as a distance from a portion of the dielectric film structure having the concentration of silicon to the first surface of the dielectric film structure increases.

14. The semiconductor device of claim 10,
wherein along the one direction, the concentration of the impurity element increases in one section of the portion of the dielectric film structure, while the concentration of silicon increases in the one section of the portion of the dielectric film structure.

15. The semiconductor device of claim 14,
wherein along the one direction, the concentration of the impurity element decreases in another section of the portion of the dielectric film structure, while the concentration of silicon decreases in the another section of the portion of the dielectric film structure.

16. The semiconductor device of claim 10,
wherein the impurity element includes nitrogen.

17. A semiconductor device comprising:
a substrate which includes a memory cell region and a peri-region;
a data storage pattern which is disposed in the memory cell region; and
a peri-gate structure which is disposed on the peri-region,
wherein the peri-gate structure includes a gate interface film that is disposed on the substrate, a dielectric film structure which is disposed on the gate interface film and includes a metal silicon oxide, and a gate electrode on the dielectric film structure,
the dielectric film structure includes an impurity element doped to the metal silicon oxide,
the dielectric film structure includes a first dielectric film region and a second dielectric film region, and
a concentration of silicon of the first dielectric film region is greater than the concentration of silicon of the second dielectric film region.

18. The semiconductor device of claim 17,
wherein the data storage pattern includes a capacitor.

19. The semiconductor device of claim 17,
wherein the peri-gate structure is disposed between the data storage pattern and the substrate.

20. The semiconductor device of claim 17, further comprising:
a word line which is disposed on the substrate of the memory cell region.
